(19) United States
(12) Patent Application Publication
(10) Pub. No.: US 2018/0179643 A1
(43) Pub. Date: Jun. 28, 2018

(54) LAMINATED FILM AND METHOD FOR MANUFACTURING LAMINATED FILM

(71) Applicant: FUJIFILM Corporation, Tokyo (JP)

(72) Inventors: Masayuki KUSUMOTO, Kanagawa (JP); Tatsuya OBA, Kanagawa (JP); Shinji HIKITA, Kanagawa (JP); Kyohisa UCHIUMI, Kanagawa (JP)

(73) Assignee: FUJIFILM Corporation, Tokyo (JP)

(21) Appl. No.: 15/840,405

(22) Filed: Dec. 13, 2017

Related U.S. Application Data
(63) Continuation of application No. PCT/JP2016/067946, filed on Jun. 16, 2016.

(30) Foreign Application Priority Data
Jun. 17, 2015 (JP) 2015-122266
Jun. 29, 2015 (JP) 2015-130410
Aug. 11, 2015 (JP) 2015-158845

(51) Int. Cl. C23C 28/02; B05D 1/26; B05D 3/02; B05D 3/06; C23C 16/34; C23C 16/50; C23C 14/20; C23C 14/34; C25D 3/38; C09D 147/00; C09D 133/00

(52) U.S. Cl. CPC C23C 28/023; B05D 1/265; B05D 3/0254; B05D 3/067; C23C 16/345; C09D 133/00; C23C 14/205; C23C 14/3464; C25D 3/38; C09D 147/00; C23C 16/50

(57) ABSTRACT

Provided are a laminated film, which can prevent quantum dots from deteriorating due to moisture or oxygen, has high durability, can narrow a frame, and has high productivity, and a method for manufacturing a laminated film. The laminated film has a functional layer laminate that has an optically functional layer and a gas barrier layer laminated on at least one main surface of the optically functional layer and an end face sealing layer that is formed by covering at least a portion of an end face of the functional layer laminate, in which the end face sealing layer includes at least two layers, and each of the layers included in the end face sealing layer is formed of a metal.

### CROSS-REFERENCE TO RELATED APPLICATIONS

This application is a Continuation of PCT International Application No. PCT/JP2016/067946 filed on Jun. 16, 2016, which was published under PCT Article 21(2) in Japanese, and which claims priority under 35 U.S.C. § 119(a) to Japanese Patent Application No. 2015-122266 filed on Jun. 17, 2015 and Japanese Patent Application No. 2015-130410 filed on Jun. 29, 2015 and Japanese Patent Application No. 2015-158845 filed on Aug. 11, 2015. The above applications are hereby expressly incorporated by reference, in their entirety, into the present application.

### BACKGROUND OF THE INVENTION

### 1. Field of the Invention

The present invention relates to a laminated film and a method for manufacturing a laminated film.

### 2. Description of the Related Art

As an image display device that consumes less power and occupies a small space, a liquid crystal display (hereinafter, referred to as LCD as well) is increasingly widely used year after year. Furthermore, in recent years, for the liquid crystal display, a further reduction in power consumption, the enhancement of color reproducibility, and the like have been required as the improvement of LCD performance.

As the power consumption of a backlight of LCD is reduced, in order to increase light use efficiency and enhance color reproducibility, the use of a quantum dot which emits light by converting the wavelength of incidence rays is suggested.

The quantum dot is a crystal in an electronic state of which the movement is restricted in all directions in a three-dimensional space. In a case where a semiconductor nanoparticle is three-dimensionally surrounded by a high-potential barrier, the nanoparticle becomes a quantum dot. The quantum dot exhibits various quantum effects. For example, the quantum dot exhibits “quantum size effect” in which the state density (energy level) of an electron becomes discrete. According to the quantum size effect, by changing the size of the quantum dot, the absorption wavelength⋅emission wavelength of light can be controlled.

Generally, by being dispersed in a resin or the like, quantum dots are used as, for example, a quantum dot film for wavelength conversion by being disposed between a backlight and a liquid crystal panel.

In a case where excitation light from a backlight is incident on a film containing quantum dots, the quantum dots are excited and emit fluorescence. At this time, in a case where quantum dots having different emission characteristics are used, light having a narrow half-width such as red light, green light, and blue light are emitted, and hence white light can be realized. Because the fluorescence from the quantum dots has a narrow half-width, by appropriately selecting the wavelength, it is possible to realize white light with high luminance or to prepare a design so as to obtain excellent color reproducibility.

Incidentally, unfortunately, the quantum dots easily deteriorate due to moisture or oxygen, and the emission intensity of the quantum dots deteriorates due to a photo-oxidation reaction. Therefore, by laminating a gas barrier film on both surfaces of a resin layer containing quantum dots (hereinafter, referred to as “quantum dot layer” as well), the quantum dot layer is protected.

However, in a case where both the main surfaces of the quantum dot layer are simply protected with the gas barrier film, unfortunately, moisture or oxygen permeates from the end face not being protected with the gas barrier film, and hence the quantum dots deteriorate.

Accordingly, a method of protecting the entirety of the periphery of the quantum dot layer with a gas barrier film is suggested.

For example, WO2012/102107A describes a composition obtained by dispersing quantum dot phosphors in a cycloolefin (co)polymer at a concentration within a range of 0.01% by mass to 20% by mass, and describes a constitution including a gas barrier layer that coats the entire surface of a resin-molded material in which quantum dots are dispersed. WO2012/102107A also describes that the gas barrier layer is a gas barrier film obtained by forming a silica film or an alumina film on at least one surface of the resin layer.

JP2013-544018A describes a display backlight unit including a remote phosphor film containing an emission quantum dot (QD) aggregate, and describes a constitution in which a QD phosphor material is sandwiched between two gas barrier films, and an inert region having gas barrier properties is located in a region sandwiched between the two gas barrier films at the periphery around the QD phosphor material.

JP2009-283441A describes a light emitting device including a color conversion layer that converts at least a portion of colored light emitted from a light source portion into another colored light and an impermeable sealing sheet that seals the color conversion layer, and describes a constitution including a second adhesive layer provided in the form of a frame along the outer periphery of a phosphor layer, that is, surrounding the planar shape of the phosphor layer, in which the second adhesive layer is formed of an adhesive material having gas barrier properties.

Furthermore, JP2009-283441A describes a constitution in which either or both of a top layer and a bottom layer which are barrier layers sealing the QD film are clamped tightly, such that the opening of the edge becomes narrow, and that the permeation of oxygen or water is inhibited.

JP2010-061098A describes a quantum dot wavelength converter including a wavelength converting portion that includes quantum dots generating light with a converted wavelength by converting the wavelength of excitation light and a dispersion medium dispersing the quantum dots and a sealing portion that seals the wavelength converting portion, in which the wavelength converting portion is sealed by subjecting an edge region of a sealing sheet to heating or thermal pressure-sensitive adhesion.

### SUMMARY OF THE INVENTION

The film containing quantum dots used in LCD is a thin film having a thickness of about 50 μm to 350 μm.

Coating the entire surface of the thin quantum dot layer with a gas barrier film is extremely difficult, and doing such a thing has a problem of poor productivity. In addition, in a case where the gas barrier film is folded, the barrier layer cracks, and this leads to a problem of the deterioration of gas barrier properties.

In a case where a constitution is adopted in which a protective layer having gas barrier properties is formed in the end face region of a quantum dot layer sandwiched between two gas barrier films, for example, the formation of the protective layer and a resin layer by, for example, a so-called dam filling method is considered. That is, a method is considered in which a protective layer is formed at the peripheral portion of one gas barrier film, a resin layer is then formed in the region surrounded by the protective layer, and then the other gas barrier film is laminated on the protective layer and the resin layer such that a film containing quantum dots is prepared.

However, because the material of the protective layer which can be formed by this method is an adhesive material or the like, high barrier properties cannot be imparted, and the gas barrier properties or the durability is insufficient.

Furthermore, in the dam filling method, the entire process is performed by a batch method, and accordingly, the problem of extremely poor productivity arises.

In addition, in a constitution in which the opening of the edge of the two gas barrier films sandwiching the quantum dot layer therebetween is narrowed or sealed, the thickness of the quantum dot layer becomes small at the edge. As a result, unfortunately, the function cannot be sufficiently performed at the edge, the area of the effectively usable region is reduced, and a frame portion is enlarged. Generally, a barrier layer having high gas barrier properties is hard and brittle. Accordingly, in a case where a gas barrier film having such a barrier layer is suddenly curved, the barrier layer cracks, the gas barrier properties deteriorate, and this leads to a problem of not being able to inhibit moisture or oxygen from permeating the quantum dot layer.

The present invention is for solvent the aforementioned problems of the related art, and objects thereof are to provide a laminated film, which can prevent an optically functional layer such as a quantum dot layer from deteriorating due to moisture or oxygen, has high durability, makes it possible to narrow a frame, and has high productivity, and to provide a method for manufacturing a laminated film.

In order to achieve the aforementioned objects, the inventors of the present invention performed an intensive study. As a result, they obtained knowledge that the aforementioned objects can be achieved by adopting a constitution including a functional layer laminate that has an optically functional layer and a gas barrier layer laminated on late least one main surface of the optically functional layer and an end face sealing layer that is formed by covering at least a portion of an end face of the functional layer laminate, in which the end face sealing layer includes at least two layers, and each of the layers included in the end face sealing layer is formed of a metal. Based on the knowledge, the inventors accomplished the present invention.

That is, the present invention provides a laminated film having the following constitution and a method for manufacturing the laminated film.

(1) A laminated film comprising a functional layer laminate having an optically functional layer and a gas barrier layer laminated on at least one main surface of the optically functional layer, and an end face sealing layer formed by covering at least a portion of an end face of the functional layer laminate, in which the end face sealing layer includes at least two layers, and each of the layers included in the end face sealing layer is formed of a metal.

(2) The laminated film described in (1), in which at least one layer included in the end face sealing layer other than a first layer included in the end face sealing layer that contacts the functional layer laminate is a metal plating layer.

(3) The laminated film described in (1) or (2), in which an outermost layer included in the end face sealing layer that is farthest from the functional layer laminate is a metal plating layer.

(4) The laminated film described in (2) or (3), in which a thickness of the metal plating layer is greater than a thickness of the first layer that contacts the functional layer laminate.

(5) The laminated film described in (4), in which the thickness of the first layer is 0.001 μm to 0.5 μm, and the thickness of the metal plating layer is 0.01 μm to 100 μm.

(6) The laminated film described in any one of (1) to (5), in which a material of the first layer that contacts the functional layer laminate is either at least one kind of metal selected from the group consisting of aluminum, titanium, chromium, copper, and nickel or an alloy containing at least one kind of these metals, and a material of each of the layers included in the end face sealing layer other than the first layer is either at least one kind of metal selected from the group consisting of aluminum, titanium, chromium, nickel, tin, copper, silver, and gold or an alloy containing at least one kind of these metals.

(7) The laminated film described in any one of (1) to (6), in which a thickness of the end face sealing layer is 0.1 μm to 100 μm.

(8) A method for manufacturing a laminated film that is for manufacturing the laminated film described any one of (1) to (7) including the end face sealing layer, which includes at least two layers and in which each of the layers included in the end face sealing layer is formed of a metal, on a lateral surface of the functional layer laminate having the optically functional layer and the gas barrier layer, the method comprising a first layer forming step of forming the first layer, which contacts the functional layer laminate, on an end face of a laminated material obtained by stacking a plurality of sheets of the functional layer laminate, and an outermost layer forming step of forming the outermost layer on the first layer formed on the end face of the laminated material, in which a method for forming the first layer is one kind of method selected from the group consisting of a sputtering method, a vacuum vapor deposition method, an ion plating method, and a plasma CVD method.

(9) The method for manufacturing the laminated film described in (8), in which a method for forming at least one layer included in the end face sealing layer other than the first layer is a metal plating treatment.

(10) A laminated film comprising a functional layer laminate having an optically functional layer and a gas barrier layer laminated on at least one main surface of the optically functional layer, and an end face sealing layer formed by covering at least a portion of an end face of the functional layer laminate, in which the end face sealing layer includes at least two layers, each of the layers included in the end face sealing layer is formed of a metal, and the optically functional layer is a cured layer obtained by curing a polymerizable composition containing phosphors and at least two or more kinds of polymerizable compounds.

(11) The laminated film described in (10), in which the polymerizable compounds include at least one kind of first polymerizable compound formed of a monofunctional polymerizable compound and at least one kind of second polymerizable compound formed of a polyfunctional polymerizable compound.

(12) The laminated film described in (11), in which the first polymerizable compound is aliphatic or aromatic alkyl (meth)acrylate containing an alkyl group having 4 to 30 carbon atoms, and the second polymerizable compound is selected from 1,6-hexanediol diacrylate, 1,10-decanediol diacrylate, 1,9-nonanediol di(meth)acrylate, tricyclodecanedimethanol diacrylate, dicyclopentanyl di(meth)acrylate, and ethoxylated bisphenol A diacrylate.

(13) The laminated film described in any one of (10) to (12), in which a modulus of elasticity of the optically functional layer at 50° C. is 1 MPa to 4,000 MPa.

(14) The laminated film described in any one of (10) to (13), in which the gas barrier layer is laminated on both the main surfaces of the optically functional layer.

(15) The laminated film described in any one of (10) to (14), in which the phosphors in the optically functional layer are quantum dots, quantum rods, or tetrapod-type quantum dots. (16) The laminated film described in any one of (10) to (15), in which at least one layer included in the end face sealing layer other than the first layer that contacts the functional layer laminate is a metal plating layer.

(17) The laminated film described in any one of (10) to (16), in which the outermost layer included in the end face sealing layer that is farthest from the functional layer laminate is a metal plating layer.

(18) The laminated film described in (16) or (17), in which a thickness of the metal plating layer is greater than a thickness of the first layer that contacts the functional layer laminate.

(19) The laminated film described in (18), in which the thickness of the first layer is 0.001 μm to 0.5 μm, and the thickness of the metal plating layer is 0.01 μm to 100 μm.

(20) The laminated film described in any one of (10) to (19), in which a material of the first layer that contacts the functional layer laminate is either at least one kind of metal selected from the group consisting of aluminum, titanium, chromium, copper, and nickel or an alloy containing at least one kind of these metals, and a material of each of the layers included in the end face sealing layer other than the first layer is either at least one kind of metal selected from the group consisting of aluminum, titanium, chromium, nickel, tin, copper, silver, and gold or an alloy containing at least one kind of these metals.

(21) The laminated film described in any one of (10) to (20), in which a thickness of the end face sealing layer is 0.1 μm to 100 μm.

(22) A method for manufacturing a laminated film that is for manufacturing the laminated film according to any one of claims 10 to 21 including the end face sealing layer, which includes at least two layers and in which each of the layers included in the end face sealing layer is formed of a metal, on a lateral surface of the functional layer laminate having the optically functional layer and the gas barrier layer, the method comprising forming the functional layer laminate, which is obtained by coating a gas barrier film having the gas barrier layer with the polymerizable composition containing phosphors and at least two or more kinds of polymerizable compounds and curing the polymerizable composition, a first layer forming step of forming the first layer, which contacts the functional layer laminate, on an end face of a laminated material obtained by stacking a plurality of sheets of the functional layer laminate, and an outermost layer forming step of forming the outermost layer on the first layer formed on the end face of the laminated material, wherein a method for forming the first layer is one kind of method selected from the group consisting of a sputtering method, a vacuum vapor deposition method, an ion plating method, and a plasma CVD method.

(23) The method for manufacturing a laminated film described in (22), in which a method for forming at least one layer included in the end face sealing layer other than the first layer is a metal plating treatment.

According to the present invention, it is possible to provide a laminated film, which can prevent a quantum dot from deteriorating due to moisture or oxygen, has high durability, makes it possible to narrow a frame, and has high productivity, and to provide a method for manufacturing a laminated film.

### BRIEF DESCRIPTION OF THE DRAWINGS

FIG. 1 is a cross-sectional view schematically showing an example of a laminated film of the present invention.

FIG. 2 is a cross-sectional view schematically showing an example of a gas barrier film used in the laminated film.

FIG. 3 is a cross-sectional view schematically showing another example of the laminated film of the present invention.

FIG. 4 is a schematic cross-sectional view for illustrating a wrapping amount of an end face sealing layer.

FIG. 5A is a schematic view for illustrating an example of a method for manufacturing a laminated film of the present invention.

FIG. 5B is a schematic view for illustrating an example of the method for manufacturing a laminated film of the present invention.

FIG. 5C is a schematic view for illustrating an example of the method for manufacturing a laminated film of the present invention.

FIG. 5D is a schematic view for illustrating an example of the method for manufacturing a laminated film of the present invention.

FIG. 6 is an optical micrograph of a cross-section of an end face of a laminated film of Comparative Example 3.

### DESCRIPTION OF THE PREFERRED EMBODIMENTS

Hereinafter, the laminated film and the method for manufacturing a laminated film of the present invention will be specifically described based on suitable examples shown in the attached drawings.

The following constituents will be described based on typical embodiments of the present invention in some cases, but the present invention is not limited to the embodiments.

In the present specification, a range of numerical values described using “to” means a range including the numerical values listed before and after “to” as a lower limit and an upper limit respectively.

The laminated film of a first aspect of the present invention is a laminated film including a functional layer laminate that has an optically functional layer and a gas barrier layer laminated on at least one main surface of the optically functional layer and an end face sealing layer that is formed by covering at least a portion of an end face of the functional layer laminate, in which the end face sealing layer includes at least two layers, and each of the layers included in the end face sealing layer is formed of a metal.

The laminated film of a second aspect of the present invention is a laminated film including a functional layer laminate that has an optically functional layer obtained by curing a polymerizable composition containing phosphors and at least two or more kinds of polymerizable compounds and a gas barrier layer laminated on at least one main surface of the optically functional layer and an end face sealing layer that is formed by covering at least portion of an end face of the functional layer laminate, in which the end face sealing layer includes at least two layers, and each of the layers included in the end face sealing layer is formed of a metal.

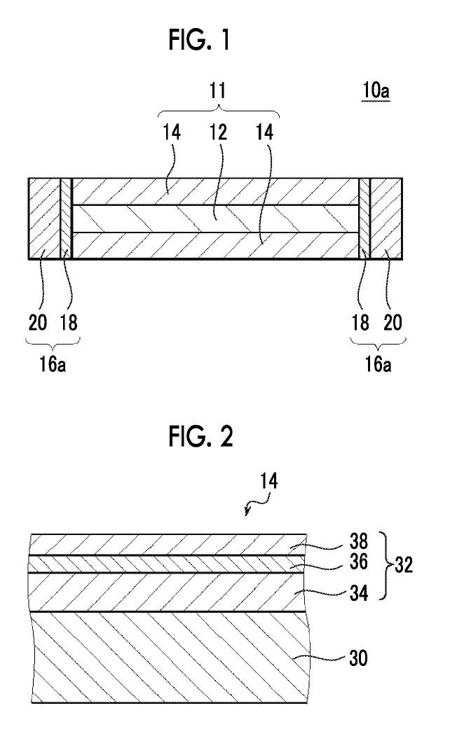

FIG. 1 is a cross-sectional view schematically showing an example of the laminated film of the present invention.

A laminated film 10a shown in FIG. 1 includes a functional layer laminate 11 that has an optically functional layer 12 and two gas barrier layers 14 laminated on both the main surfaces of the optically functional layer 12 and an end face sealing layer 16a that is formed by covering a lateral surface of the functional layer laminate 11.

The optically functional layer 12 is a layer for performing a desired function such as wavelength conversion.

For example, the optically functional layer 12 is a quantum dot layer obtained by dispersing many phosphors (quantum dots) in a matrix of a curable resin or the like, and has a function of converting the wavelength of light incident on the optically functional layer 12 and emitting the light.

For example, in a case where blue light emitted from a backlight not shown in the drawing is incident on the optically functional layer 12, by the effect of the quantum dots contained in the optically functional layer 12, the optically functional layer 12 performs wavelength conversion such that at least a portion of the blue light becomes red light or green light and emits the light.

Herein, the blue light refers to light having an emission wavelength centered at a wavelength range of 400 nm to 500 nm, the green light refers to light having an emission wavelength centered at a wavelength range of a wavelength of longer than 500 nm to a wavelength of equal to or shorter than 600 nm, and the red light refers to light having an emission wavelength centered at a wavelength range of a wavelength of longer than 600 nm to a wavelength of equal to or shorter than 680 nm.

The function of wavelength conversion that the quantum dot layer performs is not limited to the constitution in which the wavelength conversion is performed to change the blue light into the red light or the green light, and at least a portion of incidence rays may be converted into light having a different wavelength.

The quantum dot emits fluorescence by being excited with at least excitation light incident thereon.

The type of the quantum dot contained in the quantum dot layer is not particularly limited, and according to the required wavelength conversion performance or the like, various known quantum dots may be appropriately selected.

Regarding the quantum dot, for example, paragraphs “0060” to “0066” in JP2012-169271A can be referred to, but the present invention is not limited thereto. As the quantum dot, commercially available products can be used without restriction. Generally, the emission wavelength of the quantum dot can be adjusted by the composition or size of the particles.

Although it is preferable that quantum dots are evenly dispersed in a matrix, the quantum dots may be unevenly dispersed in the matrix. Furthermore, one kind of quantum dot may be used singly, or two or more kinds of quantum dots may be used in combination.

In a case where two or more kinds of quantum dots are used in combination, two or more kinds of quantum dots that emit light having different wavelengths may be used.

Specifically, known quantum dots include a quantum dot (A) having an emission wavelength centered at a wavelength range of a wavelength of longer than 600 nm to a wavelength of equal to or shorter than 680 nm, a quantum dot (B) having an emission wavelength centered at a wavelength range of a wavelength of longer than 500 nm to a wavelength of equal to or shorter than 600 nm, and a quantum dot (C) having a emission wavelength centered at a wavelength range of 400 nm to 500 nm. The quantum dot (A) emits red light by being excited with excitation light, the quantum dot (B) emits green light, and the quantum dot (C) emits blue light. For example, in a case where blue light is caused to incident on a quantum dot-containing laminate containing the quantum dot (A) and the quantum dot (B) as excitation light, by the red light emitted from the quantum dot (A), the green light emitted from the quantum dot (B), and the blue light transmitted through the quantum dot layer, white light can be realized. Furthermore, in a case where ultraviolet light is caused to incident on the quantum dot layer containing the quantum dots (A), (B), and (C) as excitation light, by the red light emitted from the quantum dot (A), the green light emitted from the quantum dot (B), and the blue light emitted from the quantum dot (C), white light can be realized.

As a quantum dot, a so-called quantum rod which has a rod shape and emits polarized light with directionality or a tetrapod-type quantum dot may be used.

In the first aspect, the type of the matrix of the quantum dot layer is not particularly limited, and various resins used in known quantum dot layers can be used.

Examples of the matrix include a polyester-based resin (for example, polyethylene terephthalate and polyethylene naphthalate), a (meth)acrylic resin, a polyvinyl chloride-based resin, a polyvinylidene chloride-based resin, and the like. Alternatively, as the matrix, it is possible to use a curable compound having a polymerizable group. The type of the polymerizable group is not particularly limited, but the polymerizable group is preferably a (meth)acrylate group, a vinyl group, or an epoxy group, more preferably a (meth)acrylate group, and even more preferably an acrylate group. In a polymerizable monomer having two or more polymerizable groups, the polymerizable groups may be the same as or different from each other.

Specifically, for example, a resin containing a first polymerizable compound and a second polymerizable compound described below can be used as a matrix.

The first polymerizable compound is preferably one or more compounds selected from the group consisting of a (meth)acrylate monomer having two or more functional groups and a monomer having two or more functional groups selected from the group consisting of an epoxy group and an oxetanyl group.

Examples of the (meth)acrylate monomer having two or more functional groups preferably include difunctional (meth)acrylate monomers such as neopentyl glycol di(meth)acrylate, 1,9-nonanediol di(meth)acrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, dicyclopentenyl (meth)acrylate, dicyclopentenyloxyethyl (meth)acrylate, and dicyclopentanyl di(meth)acrylate.

Examples of the (meth)acrylate monomer having two or more functional groups preferably include (meth)acrylate monomers having three or more functional groups such as ECH-modified glycerol tri(meth)acrylate, EO-modified glycerol tri(meth)acrylate, PO-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxy tetra(meth)acrylate, and pentaerythritol tetra(meth)acrylate.

As the monomer having two or more functional groups selected from the group consisting of an epoxy group and an oxetanyl group, an aliphatic cyclic epoxy compound, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyol obtained by adding one kind or two or more kinds of alkylene oxide to an aliphatic polyhydric alcohol such as ethylene glycol, propylene glycol, or glycerin; diglycidyl esters of aliphatic long-chain dibasic acid; glycidyl esters of higher fatty acids; a compound containing epoxycycloalkane, and the like are suitably used.

Examples of commercially available products that can be suitably used as the monomer having two or more functional groups selected from the group consisting of an epoxy group and an oxetanyl group include CELLOXIDE 2021P and CELLOXIDE 8000 manufactured by Daicel Corporation, 4-vinylcyclohexene dioxide manufactured by Sigma-Aldrich Co. LLC., and the like. One kind of these monomers can be used singly, or two or more kinds of these monomers can be used in combination.

The monomer having two or functional groups selected from the group consisting of an epoxy group and an oxetanyl group may be prepared by any method. For example, the monomer can be synthesized with reference to the documents such as “Experimental Chemistry Course 20, Organic Synthesis II”, pp. 213˜, 1992, MARUZEN SHUPPAN K.K, “The chemistry of heterocyclic compounds-Small Ring Heterocycles, part 3 Oxiranes”, Ed. By Alfred Hasfner, 1985, John & Wiley and sons, An Interscience Publication, New York, 1985, “Adhesion”, Yoshimura, Vol. 29, No. 12, 32, 1985, “Adhesion”, Yoshimura, Vol. 30, No. 5, 42, 1986, “Adhesion”, Yoshimura, Vol. 30, No. 7, 42, 1986, JP1999-100378A (JP-H11-100378A), JP2906245B, and JP2926262B.

The second polymerizable compound contains a functional group which has hydrogen bonding properties in a molecule and a polymerizable group which can cause a polymerization reaction with the first polymerizable compound.

Examples of the functional group having hydrogen bonding properties include a urethane group, a urea group, a hydroxyl group, and the like.

In a case where the first polymerizable compound is a (meth)acrylate monomer having two or more functional groups, the polymerizable group which can cause a polymerization reaction with the first polymerizable compound may be a (meth)acryloyl group, for example. In a case where the first polymerizable compound is a monomer having two or more functional groups selected from the group consisting of an epoxy group and an oxetanyl group, the polymerizable group which can cause a polymerization reaction may be an epoxy group or an oxetanyl group.

Examples of the (meth)acrylate monomer containing a urethane group include diisocyanate such as TDI, MDI, HDI, IPDI, and HMDI, polyol such as poly(propyleneoxide)diol, poly(tetramethyleneoxide)diol, ethoxylated bisphenol A, ethoxylated bisphenol S spiroglycol, caprolactone-modified diol, and carbonate diol, monomers or oligomers obtained by reacting hydroxyacrylate such as 2-hydroxyethyl (meth)acrylate, 2-hydroxypropyl (meth)acrylate, glycidol di(meth)acrylate, and pentaerythritol triacrylate, and polyfunctional urethane monomers described in JP2002-265650A, JP2002-355936A, JP2002-067238A, and the like. Specifically, examples thereof include an adduct of TDI and hydroxyethyl acrylate, an adduct of IPDI and hydroxyethyl acrylate, an adduct of HDI and pentaerythritol triacrylate (PETA), a compound obtained by making an adduct of TDI and PETA and reacting the remaining isocyanate with dodecyloxyhydroxypropyl acrylate, an adduct of 6,6 nylon and TDI, an adduct of pentaerythritol, TDI, and hydroxyethyl acrylate, and the like, but the present invention is not limited to these.

Examples of commercially available products that can be suitably used as the (meth)acrylate monomer containing a urethane group include AH-600, AT-600, UA-306H, UA-306T, UA-306I, UA-510H, UF-8001G, and DAUA-167 manufactured by KYOEISHA CHEMICAL Co., LTD, UA-160™ manufactured by SHIN-NAKAMURA CHEMICAL CO., LTD., UV-4108F and UV-4117F manufactured by OSAKA ORGANIC CHEMICAL INDUSTRY LTD, and the like. One kind of these monomers can be used singly, or two or more kinds of these monomers can be used in combination.

Examples of the (meth)acrylate monomer containing a hydroxyl group include a compound synthesized by causing a reaction between a compound having an epoxy group and (meth)acrylic acid. Typical examples of the monomer are classified into, depending on the compound having an epoxy group, a bisphenol A type, a bisphenol S type, a bisphenol F type, an epoxidized oil type, a phenol novolac type, and alicyclic type. Specific examples of the monomer include (meth)acrylate obtained by reacting an adduct of bisphenol A and epichlorohydrin with (meth)acrylic acid, (meth)acrylate obtained by reacting phenol novolac with epichlorohydrin and then reacting the product with (meth)acrylic acid, (meth)acrylate obtained by reacting an adduct of bisphenol S and epichlorohydrin with (meth)acrylic acid, (meth)acrylate obtained by reacting epoxidized soybean oil with (meth)acrylic acid, and the like. Examples of the (meth)acrylate monomer containing a hydroxyl group also include a (meth)acrylate monomer having a carboxyl group or a phosphoric acid group on the terminal, and the like, but the present invention is not limited thereto.

Examples of commercially available products that can be suitably used as the second polymerizable compound containing a hydroxyl group include epoxy ester, M-600A, 40EM, 70PA, 200PA, 80MFA, 3002M, 3002A, 3000MK, and 3000A manufactured by KYOEISHA CHEMICAL Co., LTD, 4-hydroxybutyl acrylate manufactured by Nippon Kasei Chemical Co., Ltd, monofunctional acrylate A-SA and monofunctional methacrylate SA manufactured by SHIN-NAKAMURA CHEMICAL CO., LTD., monofunctional acrylate β-carboxyethyl acrylate manufactured by DAICEL-ALLNEX LTD., JPA-514 manufactured by JOHOKU CHEMICAL CO., LTD, and the like. One kind of these can be used singly, or two or more kinds of these can be used in combination.

A mass ratio of first polymerizable compound:second polymerizable compound may be 10:90 to 99:1, and is preferably 10:90 to 90:10. It is preferable that the content of the first polymerizable compound is greater than the content of the second polymerizable compound. Specifically, (content of first polymerizable compound)/(content of second polymerizable compound) is preferably 2 to 10.

In a case where a resin containing the first polymerizable compound and the second polymerizable compound is used as a matrix, it is preferable that the matrix further contains a monofunctional (meth)acrylate monomer. Examples of the monofunctional (meth)acrylate monomer include acrylic acid, methacrylic acid, and derivatives of these, and more specifically include a monomer having one polymerizable unsaturated bond ((meth)acryloyl group) of (meth)acrylic acid in a molecule. Specific examples of the monomer include the following compounds, but the present invention is not limited thereto.

Examples of the monomer include alkyl (meth)acrylate containing an alkyl group having 1 to 30 carbon atoms, such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; aralkyl (meth)acrylate containing an aralkyl group having 7 to 20 carbon atoms, such as benzyl (meth)acrylate; alkoxyalkyl (meth)acrylate containing an alkoxyalkyl group having 2 to 30 carbon atoms, such as butoxyethyl (meth)acrylate; aminoalkyl (meth)acrylate containing a (monoalkyl or dialkyl) aminoalkyl group having 1 to 20 carbon atoms in total, such as N,N-dimethylaminoethyl (meth)acrylate; (meth)acrylate of polyalkylene glycol alkyl ether containing an alkylene chain having 1 to 10 carbon atoms and terminal alkyl ether having 1 to 10 carbon atoms, such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol; (meth)acrylate of polyalkylene glycol aryl ether containing an alkylene chain having 1 to 30 carbon atoms and terminal aryl ether having 6 to 20 carbon atoms, such as (meth)acrylate of hexaethylene glycol phenyl ether; (meth)acrylate having an alicyclic structure containing 4 to 30 carbon atoms in total, such as cyclohexyl (meth)acrylate, dicyclopentanyl (meth)acrylate, isobornyl (meth)acrylate, and methylene oxide-added cyclodecatriene (meth)acrylate; fluorinated alkyl (meth)acrylate having 4 to 30 carbon atoms in total, such as heptadecafluorodecyl (meth)acrylate; (meth)acrylate having a hydroxyl group such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono- or di(meth)acrylate of glycerol; (meth)acrylate having a glycidyl group such as glycidyl (meth)acrylate; polyethylene glycol mono(meth)acrylate having an alkylene chain containing 1 to 30 carbon atoms, such as tetraethylene glycol mono(meth)acrylate, hexaethylene glycol mono(meth)acrylate, and octapropylene glycol mono(meth)acrylate; (meth)acrylamide such as (meth)acrylamide, N,N-dimethyl (meth)acrylamide, N-isopropyl (meth)acrylamide, 2-hydroxyethyl (meth)acrylamide, and acryloylmorpholine; and the like.

The content of the monofunctional (meth)acrylate monomer with respect to the total mass (100 parts by mass) of the first polymerizable compound and the second polymerizable compound is preferably 1 to 300 parts by mass, and more preferably 50 to 150 parts by mass.

Furthermore, it is preferable that the matrix contains a compound having a long-chain alkyl group containing 4 to 30 carbon atoms. Specifically, it is preferable that at least any one of the first polymerizable compound, the second polymerizable compound, or the monofunctional (meth)acrylate monomer has a long-chain alkyl group having 4 to 30 carbon atoms. It is preferable that long-chain alkyl group is a long-chain alkyl group having 12 to 22 carbon atoms, because then the dispersibility of the quantum dots is improved. The further the dispersibility of the quantum dots is improved, the further the amount of light that goes straight to an emission surface from a light conversion layer increases. Accordingly, the improvement of the dispersibility of the quantum dots is effective for improving front luminance and front contrast.

Specifically, as the monofunctional (meth)acrylate monomer having a long-chain alkyl group containing 4 to 30 carbon atoms, butyl (meth)acrylate, octyl (meth)acrylate, lauryl (meth)acrylate, oleyl (meth)acrylate, stearyl (meth)acrylate, behenyl (meth)acrylate, butyl (meth)acrylamide, octyl (meth)acrylamide, lauryl (meth)acrylamide, oleyl (meth)acrylamide, stearyl (meth)acrylamide, behenyl (meth)acrylamide, and the like are preferable. Among these, lauryl (meth)acrylate, oleyl (meth)acrylate, and stearyl (meth)acrylate are particularly preferable.

In the laminated film of the second aspect of the present invention, the optically functional layer is a cured layer obtained by curing a polymerizable composition containing at least two or more kinds of polymerizable compounds. The polymerizable groups in at least two or more kinds of polymerizable compounds used in combination may be the same as or different from each other. It is preferable that at least two kinds of compounds described above have at least one or more common polymerizable groups.

The type of the polymerizable group is not particularly limited. The polymerizable group is preferably a (meth)acrylate group, a vinyl group, an epoxy group, or an oxetanyl group, more preferably a (meth)acrylate group, and even more preferably an acrylate group.

It is preferable that the polymerizable compounds of the present invention include at least one kind of first polymerizable compound formed of a monofunctional polymerizable compound and at least one kind of second polymerizable compound formed of a polyfunctional polymerizable compound.

Specifically, for example, it is possible to adopt an aspect in which the polymerizable compounds of the present invention include a third polymerizable compound and a fourth polymerizable compound described below.

The third polymerizable compound is a monofunctional (meth)acrylate monomer and a monomer having one functional group selected from the group consisting of an epoxy group and an oxetanyl group.

Examples of the monofunctional (meth)acrylate monomer include acrylic acid, methacrylic acid, and derivatives of these, and more specifically include an aliphatic or aromatic monomer which has one polymerizable unsaturated bond (meth)acryloyl group of (meth)acrylic acid in one molecule and has an alkyl group containing 1 to 30 carbon atoms. Specific examples of such a monomer include the following compounds, but the present invention is not limited thereto.

Examples of the aliphatic monofunctional (meth)acrylate monomer include alkyl (meth)acrylate containing an alkyl group having 1 to 30 carbon atoms, such as methyl (meth)acrylate, n-butyl (meth)acrylate, isobutyl (meth)acrylate, 2-ethylhexyl (meth)acrylate, isononyl (meth)acrylate, n-octyl (meth)acrylate, lauryl (meth)acrylate, and stearyl (meth)acrylate; alkoxyalkyl (meth)acrylate containing an alkoxyalkyl group having 2 to 30 carbon atoms, such as butoxyethyl (meth)acrylate; aminoalkyl (meth)acrylate containing a (monoalkyl or dialkyl) aminoalkyl group having 1 to 20 carbon atoms in total, such as N,N-dimethylaminoethyl (meth)acrylate; (meth)acrylate of polyalkylene glycol alkyl ether containing an alkylene chain having 1 to 10 carbon atoms and terminal alkyl ether containing 1 to 10 carbon atoms, such as (meth)acrylate of diethylene glycol ethyl ether, (meth)acrylate of triethylene glycol butyl ether, (meth)acrylate of tetraethylene glycol monomethyl ether, (meth)acrylate of hexaethylene glycol monomethyl ether, monomethyl ether (meth)acrylate of octaethylene glycol, monomethyl ether (meth)acrylate of nonaethylene glycol, monomethyl ether (meth)acrylate of dipropylene glycol, monomethyl ether (meth)acrylate of heptapropylene glycol, and monoethyl ether (meth)acrylate of tetraethylene glycol; (meth)acrylate of polyalkylene glycol aryl ether containing an alkylene chain having 1 to 30 carbon atoms and terminal aryl ether having 6 to 20 carbon atoms, such as (meth)acrylate of hexaethylene glycol phenyl ether; (meth)acrylate having an alicyclic structure containing 4 to 30 carbon atoms in total, such as cyclohexyl (meth)acrylate, dicycopentanyl (meth)acrylate, isobornyl (meth)acrylate, and ethylene oxide-added cyclodecatriene (meth)acrylate; fluorinated alkyl (meth)acrylate having 4 to 30 carbon atoms in total, such as heptadecafluorodecyl (meth)acrylate; (meth)acrylate having a hydroxyl group such as 2-hydroxyethyl (meth)acrylate, 3-hydroxypropyl (meth)acrylate, 4-hydroxybutyl (meth)acrylate, mono(meth)acrylate of triethylene glycol, tetraethylene glycol mono(meth)acrylate, hexaethylene glycol mono(meth)acrylate, octapropylene glycol mono(meth)acrylate, and mono(meth)acrylate of glycerol; (meth)acrylate having a glycidyl group such as glycidyl (meth)acrylate; polyethylene glycol mono(meth)acrylate containing an alkylene chain having 1 to 30 carbon atoms, such as tetraethylene glycol mono(meth)acrylate, hexaethylene mono(meth)acrylate, and octapropylene glycol mono(meth)acrylate; (meth)acrylamide such as (meth)acrylamide, N,N-dimethyl (meth)acrylamide, N-isopropyl (meth)acrylamide, 2-hydroxyethyl (meth)acrylamide, and acryloyl morpholine; and the like.

Examples of the aromatic monofunctional acrylate monomer include aralkyl (meth)acrylate containing an aralkyl group having 7 to 20 carbon atoms, such as benzyl (meth)acrylate.

Among the first polymerizable compounds, aliphatic or aromatic alkyl (meth)acrylate containing an alkyl group having 4 to 30 carbon atoms is preferable, and n-octyl (meth)acrylate, lauryl (meth)acrylate, stearyl (meth)acrylate, cyclohexyl (meth)acrylate, dicyclopentanyl (meth)acrylate, isobornyl (meth)acrylate, and methylene oxide-added cyclodecatriene (meth)acrylate are more preferable, because these compounds further improve the dispersibility of quantum dots. The further the dispersibility of the quantum dots is improved, the further the amount of light that goes straight to an emission surface from a light conversion layer increases. Accordingly, the improvement of the dispersibility of the quantum dots is effective for improving front luminance and front contrast.

The content of the third polymerizable compound with respect to the total mass (100 parts by mass) of the third polymerizable compound and the fourth polymerizable compound is preferably 5 to 99.9 parts by mass, and more preferably 20 to 85 parts by mass for the reason which will be described later.

The fourth polymerizable compound is a polyfunctional (meth)acrylate monomer and a monomer having and two or more functional groups selected from the group consisting of an epoxy group and an oxetanyl group in a molecule.

Among the polyfunctional (meth)acrylate monomers having two or more functional groups, examples of a difunctional (meth)acrylate monomer preferably include neopentyl glycol di(meth)acrylate, 1,6-hexanediol di(meth)acrylate, 1,9-nonanediol di(meth)acrylate, 1,10-decanediol diacrylate, tripropylene glycol di(meth)acrylate, ethylene glycol di(meth)acrylate, tetraethylene glycol di(meth)acrylate, hydroxypivalic acid neopentyl glycol di(meth)acrylate, polyethylene glycol di(meth)acrylate, tricyclodecanedimethanol diacrylate, ethoxylated bisphenol A diacrylate, and the like.

Among the polyfunctional (meth)acrylate monomers having two or more functional groups, examples of a (meth)acrylate monomer having three or more functional groups preferably include ECH-modified glycerol tri(meth)acrylate, EO-modified glycerol tri(meth)acrylate, PO-modified glycerol tri(meth)acrylate, pentaerythritol triacrylate, pentaerythritol tetraacrylate, EO-modified phosphoric acid triacrylate, trimethylolpropane tri(meth)acrylate, caprolactone-modified trimethylolpropane tri(meth)acrylate, EO-modified trimethylolpropane tri(meth)acrylate, PO-modified trimethylolpropane tri(meth)acrylate, tris(acryloxyethyl)isocyanurate, dipentaerythritol hexa(meth)acrylate, dipentaerythritol penta(meth)acrylate, caprolactone-modified dipentaerythritol hexa(meth)acrylate, dipentaerythritol hydroxypenta(meth)acrylate, alkyl-modified dipentaerythritol penta(meth)acrylate, dipentaerythritol poly(meth)acrylate, alkyl-modified dipentaerythritol tri(meth)acrylate, ditrimethylolpropane tetra(meth)acrylate, pentaerythritol ethoxytetra(meth)acrylate, pentaerythritol tetra(meth)acrylate, and the like.

As a polyfunctional monomer, it is also possible to use a (meth)acrylate monomer having a urethane bond in a molecule, specifically, an adduct of TDI and hydroxyethyl acrylate, an adduct of IPDI and hydroxyethyl acrylate, an adduct of HDI and pentaerythritol triacrylate (PETA), a compound obtained by making an adduct of TDI and PETA and reacting the remaining isocyanate with dodecyloxyhydroxypropyl acrylate, an adduct of 6,6 nylon and TDI, an adduct of pentaerythritol, TDI, and hydroxyethyl acrylate, and the like.

As the monomer having two or more functional groups selected from the group consisting of an epoxy group and an oxetanyl group, for example, an aliphatic cyclic epoxy compound, bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers; polyglycidyl ethers of polyether polyol obtained by adding one kind or two or more kinds of alkylene oxide to an aliphatic polyhydric alcohol such as ethylene glycol, propylene glycol, or glycerin; diglycidyl esters of aliphatic long-chain dibasic acid; glycidyl esters of higher fatty acids; a compound containing epoxycycloalkane, and the like are suitably used.

Examples of commercially available products that can be suitably used as the monomer having two or more functional groups selected from the group consisting of an epoxy group and an oxetanyl group include CELLOXIDE 2021P and CELLOXIDE 8000 manufactured by Daicel Corporation, 4-vinylcyclohexene dioxide manufactured by Sigma-Aldrich Co. LLC., and the like.

The monomer having two or functional groups selected from the group consisting of an epoxy group and an oxetanyl group may be prepared by any method. For example, the monomer can be synthesized with reference to the documents such as “Experimental Chemistry Course 20, Organic Synthesis II”, pp. 213˜, 1992, MARUZEN SHUPPAN K.K, “The chemistry of heterocyclic compounds-Small Ring Heterocycles, part 3 Oxiranes”, Ed. By Alfred Hasfner, 1985, John & Wiley and sons, An Interscience Publication, New York, 1985, “Adhesion”, Yoshimura, Vol. 29, No. 12, 32, 1985, “Adhesion”, Yoshimura, Vol. 30, No. 5, 42, 1986, “Adhesion”, Yoshimura, Vol. 30, No. 7, 42, 1986, JP1999-100378A (JP-H11-100378A), JP2906245B, and JP2926262B.

The content of the fourth polymerizable compound with respect to the total mass (100 parts by mass) of the third polymerizable compound and the fourth polymerizable compound is preferably 0.1 parts by mass to 95 parts by mass, and more preferably 15 parts by mass to 80 parts by mass for the reason which will be described later.

At the time of providing the end face sealing layer, which will be described later, on the optically functional layer of the present application, by a sputtering method, a vacuum vapor deposition method, an ion plating method, and a plasma CVD method, a metal thin film is formed on the end face of the functional layer laminate. For example, in a case where the metal thin film is formed on the end face of a matrix of a cured material formed only of a monofunctional (meth)acrylate compound by a sputtering method, the matrix cannot withstand the internal stress of the metal thin film. Therefore, the metal thin film has a defect, and hence sufficient barrier properties cannot be imparted. In contrast, in a matrix formed only of a polyfunctional (meth)acrylate compound, even though a defect is not caused in the metal thin film, the smoothness of the end face is poor because the metal thin film is hard and brittle, and the end face of the metal thin film cannot be uniformly coated. As a result, the barrier properties deteriorate. In the present invention, a monofunctional (meth)acrylate monomer and a polyfunctional (meth)acrylate monomer are mixed together within the aforementioned appropriate range, such that the matrix endure the film shrinkage at the time of forming the metal thin film and that no defect is caused in the metal thin film on the end face of the matrix. Accordingly, smoothness can be secured, and an end face sealing layer having high barrier properties can be formed on the end face.

A modulus of elasticity of the matrix as a cured material, on which the optically functional layer of the present application is formed, measured at 50° C. is preferably equal to or greater than 1 MPa and equal to or smaller than 4,000 MPa, and more preferably equal to or greater than 10 MPa and equal to or smaller than 3,000 MPa. For example, in a sputtering method, a film surface temperature at the time of forming a film becomes up to about 50° C. Therefore, the modulus of elasticity at 50° C. is used as a value of physical properties of the matrix enduring the film shrinkage. In a case where the modulus of elasticity is within the above range, it is possible to reduce the defect in the metal thin film of the end face sealing layer.

(Viscosity Adjuster)

If necessary, the polymerizable composition may contain a viscosity adjuster. It is preferable that the viscosity adjuster is a filler having a particle diameter of 5 nm to 300 nm. It is also preferable that the viscosity adjuster is a thixotropic agent. In the present invention and the present specification, the thixotropic properties refer to properties in which the viscosity of a liquid composition is reduced as a shearing speed is increased. The thixotropic agent refers to a material that performs a function of imparting thixotropic properties to the composition by being incorporated into the liquid composition. Specific examples of the thixotropic agent include fumed silica, alumina, silicon nitride, titanium dioxide, calcium carbonate, zinc oxide, talc, mica, feldspar, kaolinite, (kaolin clay), pyrophyllite (agalmatolite clay), sericite, bentonite, smectite⋅vermiculites (montmorillonite, beidellite, nontronite, saponite, and the like), organic bentonite, organic smectite, and the like.

In an aspect, in a case where the shearing speed is 500 s⁻¹, the viscosity of the polymerizable composition is 3 mPa·s to 50 mPa·s. It is preferable that the viscosity of the polymerizable composition is equal to or higher than 100 mPa·s in a case where the shearing speed is 1 s⁻¹. In order to adjust the viscosity within the above range, it is preferable to use a thixotropic agent. In a case where the shearing speed is 500 s⁻¹, the viscosity of the polymerizable composition is 3 mPa·s to 50 mPa·s, and it is preferable that the viscosity of the polymerizable composition is equal to or higher than 100 mPa·s in a case where the shearing speed is 1 s⁻¹, for the following reason.

Examples of the method for manufacturing the functional layer laminate include a manufacturing method which includes, as will be described later, steps of coating a first substrate with the polymerizable composition, then bonding a second substrate onto the polymerizable composition, and then forming a wavelength conversion layer by curing the polymerizable composition. In the aforementioned manufacturing method, at the time of coating the first substrate with the polymerizable composition, in order to prevent the occurrence of coating streaks, it is desirable to uniformly coat the substrate and to form a coating film having a uniform film thickness. In order to form such a coating film, from the viewpoint of coating properties and leveling properties, it is preferable that the coating solution (polymerizable composition) has low viscosity. In contrast, in order to uniformly bond the second substrate onto the coating solution with which the first substrate is coated, it is preferable that the resistance against the pressure at the time of bonding is high, and in this respect, a coating solution having high viscosity is preferable. The aforementioned shearing speed of 500 s⁻¹ a typical value of the shearing speed applied to the coating solution with which the first substrate is coated, and the shearing speed of 1 s⁻¹ is a typical value of the shearing speed applied to the coating solution immediately before the second substrate is bonded to the coating solution. Herein, the shearing speed of 1 s⁻¹ is merely a typical value. At the time of bonding the second substrate onto the coating solution with which the first substrate is coated, as long as the second substrate is bonded in a state where the first substrate and the second substrate are being transported at the same speed, the shearing speed applied to the coating solution is about 0 s⁻¹, and the shearing speed applied to the coating solution in the actual manufacturing step is not limited to 1 s⁻¹. Likewise, the shearing speed of 500 s⁻¹ is merely a typical value, and the shearing speed applied to the coating solution in the actual manufacturing step is not limited to 500 s⁻¹. From the viewpoint of uniform coating and uniform bonding, it is preferable to adjust the viscosity of the polymerizable composition, such that the viscosity becomes 3 mPa·s to 50 mPa·s in a case where the typical value of the shearing speed applied to the coating solution is 500 s⁻¹ at the time of coating the first substrate with the coating solution, and that the viscosity becomes equal to or higher than 100 mPa·s in a case where the typical value of the shearing speed applied to the coating solution is 1 s⁻¹ immediately before the second substrate is bonded onto the coating solution with which the first substrate is coated.

(Solvent)

If necessary, the aforementioned polymerizable composition may contain a solvent. In this case, the type of the solvent used and the amount of the solvent added are not particularly limited. For example, as the solvent, it is possible to use one kind of organic solvent or two or more kinds of organic solvents by mixing them together.

Furthermore, the resin which becomes a matrix may contain a compound having a fluorine atom, such as trifluoroethyl (meth)acrylate, pentafluoroethyl (meth)acrylate, (perfluorobutyl)ethyl (meth)acrylate, perfluorobutyl-hydroxypropyl (meth)acrylate, (perfluorohexyl)ethyl (meth)acrylate, octafluoropentyl (meth)acrylate, perfluorooctyl ethyl (meth)acrylate, and tetrafluoropropyl (meth)acrylate. In a case where the resin contains these compounds, the coating properties can be further improved.

The total amount of the resin, which becomes a matrix, in the quantum dot layer is not particularly limited. The total amount of the resin with respect to a total of 100 parts by mass of the quantum dot layer is preferably 90 parts by mass to 99.9 parts by mass, and more preferably 92 parts by mass to 99 parts by mass.

The thickness of the quantum dot layer is not particularly limited. However, in view of handleability and emission characteristics, the thickness of the quantum dot layer is preferably 5 μm to 200 μm, and more preferably 10 μm to 150 μm.

The aforementioned thickness means an average thickness which can be determined by measuring thicknesses of ten or more random spots in the quantum dot layer and calculating an arithmetic mean thereof.

In the first aspect, the method for forming the quantum dot layer is not particularly limited, and the quantum dot layer may be formed by a known method. For example, the quantum dot layer can be formed by preparing a coating composition by means of mixing quantum dots, a resin which will become a matrix, and a solvent together, coating the gas barrier layer 14 with the coating composition, and curing the coating composition.

In the second aspect, the quantum dot layer can be formed by a method of preparing a polymerizable composition containing phosphors (quantum dots) and at least two or more kinds of polymerizable compounds, coating the gas barrier layer 14 with the polymerizable composition, and curing the polymerizable composition.

If necessary, a polymerization initiator, a silane coupling agent, and the like may be added to the coating composition that will become the quantum dot layer.

The gas barrier layer 14 is a layer which is laminated on a main surface of the optically functional layer 12 and has gas barrier properties. That is, the gas barrier layer 14 is a member for inhibiting the permeation of moisture or oxygen from the main surface of the optically functional layer 12 by covering the main surface of the optically functional layer 12.

A water vapor permeability of the gas barrier layer 14 is preferably equal to or lower than 1×10⁻³ [g/(m²·day)].

Furthermore, an oxygen permeability of the gas barrier layer 14 is preferably equal to or lower than 1×10⁻² [cc/(m²·day·atm)].

By using the gas barrier layer 14 having a low water vapor permeability and a low oxygen permeability, that is, by using the gas barrier layer 14 having high gas barrier properties, it is possible to prevent moisture or oxygen from permeating the optically functional layer 12 and to more suitably prevent the deterioration of the optically functional layer 12.

The water vapor permeability was measured by a Mocon method under the condition of a temperature of 40° C. and a relative humidity of 90% RH. In a case where the water vapor permeability exceeded a measurement limit of the Mocon method, the water vapor permeability was measured by a calcium corrosion method (method described in JP2005-283561A).

The oxygen permeability was measured using a measurement instrument (manufactured by NIPPON API CO., LTD.) adopting an APIMS method (atmospheric pressure ionization mass spectrometry), under the condition of a temperature of 25° C. and a humidity of 60% RH. As an SI unit of the oxygen permeability, fm/(s·Pa) is known. 1 fm/(s·Pa) can be converted into 8.752 cc/(m²·day·atm) (fm: femtometer).

The thickness of the gas barrier layer 14 is preferably 5 μm to 100 μm, more preferably 10 μm to 70 μm, and particularly preferably 15 μm to 55 μm.

It is preferable that the thickness of the gas barrier layer 14 is equal to or smaller than 100 μm, because then the total thickness of the laminated film 10a including the optically functional layer 12 can be reduced.

Furthermore, it is preferable that the thickness of the gas barrier layer 14 is equal to or greater than 5 μm, because then the thickness of the optically functional layer 12 can be made uniform at the time of forming the optically functional layer 12 between two gas barrier layers 14.

As the gas barrier layer 14, gas barrier films having desired gas barrier properties can be appropriately used without restriction.

For example, a gas barrier film is suitably used which includes a gas barrier support 30 and at least one organic layer and at least one inorganic layer as a barrier layer 32 that is on the support 30.

FIG. 2 is a cross-sectional view schematically showing an example of a gas barrier film.

The gas barrier film (gas barrier layer) 14 shown in FIG. 2 has the barrier layer 32 obtained by laminating an organic layer 34, an inorganic layer 36, and an organic layer 38 in this order and the gas barrier support 30 supporting the barrier layer 32.

The gas barrier film 14 may have at least one inorganic layer 36 on the gas barrier support 30, and preferably has one or more combinations of the inorganic layer 36 and the organic layer 34 which becomes the base of the inorganic layer 36. Accordingly, the number of combinations of the inorganic layer 36 and the organic layer 34 as a base included in the gas barrier layer 14 may be two, three, or greater. The organic layer 34 functions as an underlayer for appropriately forming the inorganic layer 36. As the number of combinations of the organic layer 34 as a base and the inorganic layer 36 laminated increases, a gas barrier film having better gas barrier properties is obtained.

In the example shown in FIG. 2, the organic layer 38 is the outermost layer (layer on the side opposite to the gas barrier support 30) of the barrier layer 32. However, the present invention is not limited thereto, and the inorganic layer 36 may be the outermost layer.

Herein, basically, the optically functional layer 12 is laminated on the barrier layer 32 side. Accordingly, by using the inorganic layer 36 as the outermost layer of the barrier layer 32 and laminating the optically functional layer 12 on the barrier layer 32 side, even though outgas is released from the gas barrier support 30 or the organic layer 34, the outgas is blocked by the inorganic layer 36 and prevented from reaching the optically functional layer 12.

As the gas barrier support 30 of the gas barrier layer 14, it is possible to use various materials that are used as a support in known gas barrier films.

Among these, films formed of various plastics (polymer material/resin material) are suitably used, because these films make it easy to obtain a thin or lightweight support and are suitable for making a flexible support.

Specifically, plastic films formed of polyethylene (PE), polyethylene naphthalate (PEN), polyamide (PA), polyethylene terephthalate (PET), polyvinyl chloride (PVC), polyvinyl alcohol (PVA), polyacrylonitrile (PAN), polyimide (PI), transparent polyimide, polymethyl methacrylate resin (PMMA), polycarbonate (PC), polyacrylate, polymethacrylate, polypropylene (PP), polystyrene (PS), ABS, a cyclic olefin copolymer (COC), a cycloolefin polymer (COP), and triacetyl cellulose (TAC) can be suitably exemplified.

The thickness of the gas barrier support 30 may be appropriately set according to the purpose or size. According to the examination performed by the inventors of the present invention, the thickness of the gas barrier support 30 is preferably about 10 μm to 100 μm. In a case where the thickness of the gas barrier support 30 is within the above range, in view of making a lightweight or thin support, preferable results are obtained.

To the surface of the plastic film of which the gas barrier support 30 is formed, the functions of preventing reflection, controlling phase difference, improving light extraction efficiency, and the like may be imparted.

The barrier layer 32 has the inorganic layer 36 which mainly exhibits gas barrier properties, the organic layer 34 which becomes the underlayer of the inorganic layer 36, and the organic layer 38 that protects the inorganic layer 36.

The organic layer 34 becomes the underlayer of the inorganic layer 36 which mainly exhibits gas barrier properties in the gas barrier film 14.

As the organic layer 34, various materials used as the organic layer 34 in general gas barrier films can be used. For example, the organic layer 34 is a film containing an organic compound as a main component, and basically, a material formed by crosslinking a monomer and/or oligomer can be used.

The gas barrier film 14 has the organic layer 34 which becomes the base of the inorganic layer 36. Therefore, the asperities on the surface of the gas barrier support 30, foreign substances having adhered to the surface, and the like are concealed, and hence a deposition surface for the inorganic layer 36 can be appropriately prepared. As a result, an appropriate inorganic layer 36 having no crack, fissure, and the like can be formed on the entirety of the deposition surface without voids. Consequently, it is possible to obtain a high gas barrier performance in which the water vapor permeability is equal to or lower than 1×10⁻³ [g/(m²·day)] and an oxygen permeability is equal to or lower than 1×10⁻² [cc/(m²·day·atm)].

The gas barrier film 14 has the organic layer 34 that becomes the base as described above, and as a result, the organic layer 34 functions as a cushion for the inorganic layer 36. Accordingly, in a case where the inorganic layer 36 takes an external impact or the like, due to the cushioning effect of the organic layer 34, the damage of the inorganic layer 36 can be prevented.

Consequently, in the laminated film 10a, the gas barrier film 14 appropriately demonstrates the gas barrier performance, and hence the deterioration of the optically functional layer 12 resulting from moisture or oxygen can be suitably prevented.

In the gas barrier film 14, as the material for forming the organic layer 34, various organic compounds (resin/polymer compound) can be used.

Specifically, thermoplastic resins such as polyester, an acrylic resin, a methacrylic resin, a methacrylic acid-maleic acid copolymer, polystyrene, a transparent fluorine resin, polyimide, fluorinated polyimide, polyamide, polyamide imide, polyether imide, cellulose acylate, polyurethane, polyether ether ketone, polycarbonate, alicyclic polyolefin, polyarylate, polyether sulfone, polysulfone, fluorene ring-modified polycarbonate, alicyclic ring-modified polycarbonate, fluorene ring-modified polyether, and an acryloyl compound, polysiloxane, and films of other organic silicon compounds can be suitably exemplified. A plurality of these materials may be used in combination.

Among these, in view of excellent glass transition temperature and hardness, an organic layer 34 is suitable which is constituted with a polymer of a radically polymerizable compound and/or a cationically polymerizable compound having an ether group as a functional group.

Particularly, an acrylic resin or a methacrylic resin, which contains a polymer of a monomer or an oligomer of acrylate and/or methacrylate as a main component and has a glass transition temperature of equal to or higher than 120° C., can be suitably exemplified as the organic layer 34, because such a resin has excellent hardness, low refractive index, high transparency, excellent optical characteristics, and the like. Especially, an acrylic resin or a methacrylic resin can be suitably exemplified which contains, as a main component, a monomer or an oligomer of acrylate and/or methacrylate having two or more functional groups, particularly, three or more functional groups, such as dipropylene glycol di(meth)acrylate (DPGDA), trimethylolpropane tri(meth)acrylate (TMPTA), or dipentaerythritol hexa(meth)acrylate (DPHA). Furthermore, it is preferable to use a plurality of acrylic resins or methacrylic resins described above.

In a case where the organic layer 34 is formed of the acrylic resin or the methacrylic resin described above, the inorganic layer 36 can be formed on a base having a proper skeleton, and hence the inorganic layer 36 can be formed as a denser film having high gas barrier properties.

The thickness of the organic layer 34 is preferably 1 μm to 5 μm.

In a case where the thickness of the organic layer 34 is equal to or greater than 1 μm, the deposition surface for the inorganic layer 36 can be more suitably and appropriately prepared, and hence the inorganic layer 36 having no crack, fissure, and the like can be formed on the entirety of the deposition surface.

Furthermore, in a case where the thickness of the organic layer 34 is equal to or smaller than 5 μm, it is possible to suitably prevent the occurrence of problems such as cracking of the organic layer 34 and the curling of the gas barrier film 14 that arise in a case where the organic layer 34 is too thick.

Considering the aforementioned points, the thickness of the organic layer 34 is more preferably 1 μm to 5 μm.

In a case where the gas barrier film has a plurality of organic layers 34 as an underlayer, the organic layers may have the same thickness or different thicknesses.

In a case where the gas barrier film has a plurality of organic layers 34, the organic layers may be formed of the same material or different materials. However, in view of productivity or the like, it is preferable that all of the organic layers are formed of the same material.

The organic layer 34 may be formed by a known method such as a coating method or flash vapor deposition.

Furthermore, in order to enhance the adhesiveness between the organic layer 34 and the inorganic layer 36 that becomes the underlayer of the organic layer 34, it is preferable that the organic layer 34 contains a silane coupling agent.

On the organic layer 34, the inorganic layer 36 is formed using the organic layer 34 as a base. The inorganic layer 36 is a film containing an inorganic compound as a main component and mainly exhibits gas barrier properties in the gas barrier layer 14.

As the inorganic layer 36, various films can be used which exhibit gas barrier properties and are formed of an inorganic compound such as an oxide, a nitride, or an oxynitride.

Specifically, films formed of inorganic compounds including a metal oxide such as aluminum oxide, magnesium oxide, tantalum oxide, zirconium oxide, titanium oxide, an indium tin oxide (ITO); a metal nitride such as aluminum nitride; a metal carbide such as aluminum carbide; an oxide of silicon such as silicon oxide, silicon oxynitride, silicon oxycarbide, and silicon oxynitrocarbide; a nitride of silicon such as silicon nitride and silicon nitrocarbide; a carbide of silicon such as silicon carbide; hydroxides of these; a mixture of two or more kinds of these; and hydrogenous substances of these can be suitably exemplified.

Particularly, films formed of a silicon compound such as an oxide of silicon, a nitride of silicon, and an oxynitride of silicon can be suitably exemplified, because these films have high transparency and can exhibit excellent gas barrier properties. Among these, a film formed of silicon nitride can be particularly suitably exemplified because this film exhibits better gas barrier properties and has high transparency.

In a case where the gas barrier film has a plurality of inorganic layers 36, the inorganic layers 36 may be formed of the same material or different materials. However, considering productivity and the like, it is preferable that all of the inorganic layers 36 are formed of the same material.

The thickness of the inorganic layer 36 may be appropriately determined according to the material forming the inorganic layer 36, such that intended gas barrier properties can be exhibited. According to the examination performed by the inventors of the present invention, the thickness of the inorganic layer 36 is preferably 10 nm to 200 nm.

In a case where the thickness of the inorganic layer 36 is equal to or greater than 10 nm, the inorganic layer 36 stably demonstrating sufficient gas barrier performance can be formed. Generally, in a case where the inorganic layer 36 is brittle and too thick, the inorganic layer 36 is likely to experience cracking, fissuring, peeling and the like. However, in a case where the thickness of the inorganic layer 36 is equal to or smaller than 200 nm, the occurrence of cracks can be prevented.

Considering the aforementioned points, the thickness of the inorganic layer 36 is preferably 10 nm to 100 nm, and particularly preferably 15 nm to 75 nm.

Furthermore, in a case where the gas barrier film has a plurality of inorganic layers 36, the inorganic layers 36 may have the same thickness or different thicknesses.

The inorganic layer 36 may be formed by a known method according to the material forming the inorganic layer 36. Specifically, plasma CVD such as capacitively coupled plasma (CCP)-chemical vapor deposition (CVD) or inductively coupled plasma (ICP)-CVD, sputtering such as magnetron sputtering or reactive sputtering, and a vapor-phase deposition method such as vacuum vapor deposition can be suitably exemplified.

The organic layer 38 is a layer which is formed as an outermost layer of the barrier layer 32 and is for protecting the inorganic layer 36.

As the organic layer 38, it is possible to use various materials that are the same as the materials used for the aforementioned organic layer 34.

Furthermore, the organic layer 38 may be formed by a known method such as a coating method or flash vapor deposition similarly to the aforementioned organic layer 34.

The thickness of the organic layer 38 which becomes the outermost layer of the barrier layer 32 is preferably 80 nm to 1,000 nm. In a case where the thickness of the organic layer 38 is equal to or greater than 80 nm, the inorganic layer 36 can be sufficiently protected. It is preferable that the thickness of the organic layer 38 is equal to or smaller than 1,000 nm, because then cracking and a reduction in permeability can be prevented.

From the viewpoint described above, the thickness of the organic layer 38 is more preferably 80 nm to 500 nm.

The organic layer 38 as a protective layer and the organic layer 34 as an underlayer may be formed of the same material or different materials. However, in view of productivity and the like, it is preferable that all of the organic layers are formed of the same material.

Furthermore, in order to improve the adhesiveness between the organic layer 38 and the inorganic layer 36 that becomes the underlayer of the organic layer 38, it is preferable that the organic layer 38 contains a silane coupling agent.

Next, the end face sealing layer 16a will be described.

The end face sealing layer 16a is a member formed by covering at least a portion of the end face of the functional layer laminate 11 which has the optically functional layer 12 and two gas barrier layers 14 laminated such that the optically functional layer 12 is sandwiched therebetween.

In the present invention, the end face sealing layer 16a includes at least two layers, and each of the layers included in the end face sealing layer 16a is formed of a metal. The end face sealing layer 16a is a member which exhibits gas barrier properties and is for inhibiting the permeation of moisture or oxygen from the end face of the optically functional layer 12.

In the laminated film 10a shown in FIG. 1, the end face sealing layer 16a includes two layers consisting of a first layer 18 which is formed in a state of contacting the end face of the functional layer laminate 11 and an outermost layer 20 which is laminated on the first layer 18 and farthest from the functional layer laminate 11.

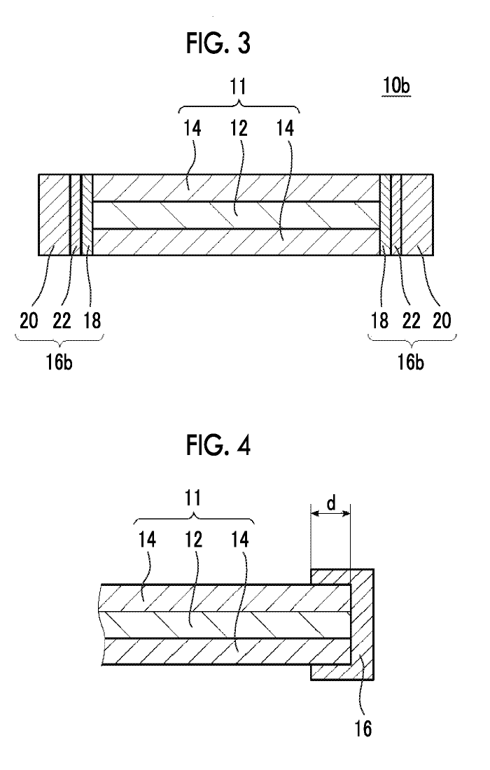

In the present invention, the end face sealing layer is not limited to the constitution including two layers and may include three or more layers. For example, similarly to the an end face sealing layer 16b of a laminated film 10b shown in FIG. 3, the end face sealing layer may be constituted with three layers including the first layer 18 formed in a state of contacting the end face of the functional layer laminate 11, a second layer 22 laminated on the first layer 18, and the outermost layer 20 which is laminated on the second layer 22 and farthest from the functional layer laminate 11.

As shown in FIGS. 1 and 3, the end face sealing layer 16 is laminated on the end face of the functional layer laminate 11. Therefore, the lamination direction of the respective layers (the first layer 18, the second layer 22, and the outermost layer 20) constituting the end face sealing layer 16 is a direction perpendicular to the end face of the functional layer laminate 11 and orthogonal to the lamination direction of the functional layer laminate 11.

In the present invention, all of the layers constituting the end face sealing layer 16 are formed of a metal. That is, in the laminated film 10a shown in FIG. 1, the first layer 18 and the outermost layer 20 are formed of a metal. Furthermore, in the laminated film 10b shown in FIG. 3, all of the first layer 18, the second layer 22, and the outermost layer 20 are formed of a metal.

As described above, a gas barrier film is laminated on both the main surfaces of the quantum dot layer containing quantum dots that easily deteriorate due to moisture or oxygen, such that the quantum dot layer is protected. However, in a case where both the main surfaces of the quantum dot layer are protected simply with the gas barrier film, moisture or oxygen permeates from the end face not being protected with the gas barrier film, and this leads to a problem of deterioration of the quantum dots.

For solving the problem, there is suggested a constitution in which the entire surface of the quantum dot layer is protected with a gas barrier film such that the permeation of moisture or oxygen from the end face is inhibited, a constitution in which a protective layer having gas barrier properties is formed in an end face region of the quantum dot layer sandwiched between two gas barrier films, a constitution in which the opening of the edge of two gas barrier films sandwiching the quantum dot layer therebetween is narrowed, or the like.

However, coating the entire surface of a thin quantum dot layer with a gas barrier film is extremely difficult, has poor productivity, and results in a problem in that in a case where the gas barrier film is folded, the barrier layer cracks, and hence the gas barrier properties deteriorate.

Furthermore, in a case where the constitution is adopted in which a protective layer having gas barrier properties is formed in the end face region of the quantum dot layer sandwiched between two gas barrier films, a material having high barrier properties cannot be used as a material of the protective layer, and the gas barrier properties or durability becomes insufficient. In addition, in a case where such a laminated film is prepared, there is a problem in that the productivity is extremely poor because the entire process is performed by a batch method.

In a case where the constitution is adopted in which the opening at the edge of two gas barrier films sandwiching the quantum dot layer therebetween is narrowed, the quantum dot layer at the edge becomes thin. Accordingly, the performance cannot be sufficiently demonstrated at the edge, the area of an effectively usable region is reduced, and this leads to a problem of enlargement of a frame portion. Generally, a barrier layer having high gas barrier properties is hard and brittle. Therefore, in a case where the gas barrier film having such a barrier layer is suddenly curved, the barrier layer cracks, the gas barrier properties deteriorate, and this leads to a problem in that it is impossible to inhibit moisture or oxygen from permeating the quantum dot layer.

In contrast, the present invention has a constitution including a functional layer laminate that has an optically functional layer and a gas barrier layer laminated on at least one main surface of the optically functional layer and an end face sealing layer that is formed by covering at least a portion of the end face of the functional layer laminate, in which the end face sealing layer includes at least two layers, and each of the layers included in the end face sealing layer is formed of a metal.

By sealing the end face of the functional layer laminate with two or more metal layers, high gas barrier properties can be exhibited, and moisture or oxygen is inhibited from permeating the optically functional layer. Therefore, it is possible to prevent the quantum dots from deteriorating due to moisture or oxygen, extend the service life, and improve the durability.

Furthermore, because the end face sealing layer formed of a metal is simply formed on the end face of the functional layer laminate, the optically functional layer is not thinned, or the gas barrier layer is not curved. Consequently, a large region in which the optically functional layer can be effectively used can be maintained, and the frame can be narrowed.

In addition, the first layer of the end face sealing layer that contacts the functional layer laminate is formed of a material exhibiting high adhesiveness with respect to the functional layer laminate by a formation method which can enhance the adhesiveness, and a layer exhibiting high gas barrier properties can be formed as the second layer and the following layers. Therefore, it is possible to prevent the end face sealing layer from being peeled from the functional layer laminate, and hence high durability is obtained.

Moreover, as will be specifically described later, at the time of forming the end face sealing layer, each of the layers included in the end face sealing layer can be formed in a state where a plurality of sheets of functional layer laminates are laminated. Therefore, a plurality of laminated films can be collectively formed, and the productivity can be improved.

It is preferable that the oxygen permeability of the end face sealing layer 16 is preferably equal to or lower than 1×10⁻² [cc/(m²·day·atm)].

By forming the end face sealing layer 16 having low oxygen permeability, that is, high gas barrier properties on the end face of the functional layer laminate 11, it is possible to more suitably prevent moisture or oxygen from permeating the optically functional layer 12 and to more suitably prevent the deterioration of the optically functional layer 12.

The thickness of the end face sealing layer 16 in a direction perpendicular to the end face of the functional layer laminate 11 is preferably within a range of 0.1 μm to 100 μm, more preferably 0.5 μm to 50 μm, and particularly preferably 1 μm to 10 μm.

In a case where the thickness of the end face sealing layer 16 is equal to or greater than 0.1 μm, sufficient gas barrier performance can be stably demonstrated. In a case where the thickness of the end face sealing layer 16 is equal to or smaller than 100 μm, the occurrence of cracks can be suitably prevented.

As will be described later, it is preferable that the laminated film of the present invention is prepared by forming the end face sealing layer on the end face in a state where a plurality of sheets of functional layer laminates are stacked and then separating the laminates. However, in a case where the end face sealing layer 16 is too thick, it is not easy to separate the laminated film. In this respect, the thickness of the end face sealing layer 16 is preferably equal to or smaller than 100 μm.

Although the end face sealing layer 16 may be formed such that it covers at least a portion of the end face of the functional layer laminate 11, it is preferable that the end face sealing layer 16 is formed by covering the entirety of the periphery of the end face.

For example, in a case where the functional layer laminate 11 has a rectangular main surface, the end face sealing layer 16 may be formed on at least one end face, and preferably formed on all of the four end faces.

The shape of the main surface of the functional layer laminate 11 (shape of the laminated film 10) is not limited to the rectangular shape, and various shapes can be adopted such as a square shape, a circular shape, and a polygonal shape. Accordingly, the end face sealing layer may be formed to cover at least a portion of the end face, and is preferably formed to cover the entirety of the periphery of the end face.

It is preferable that the end face sealing layer 16 is formed only on the end face of the functional layer laminate 11 and does not wrap around the main surface of the functional layer laminate 11 too much, for the following reasons. In a case where the end face sealing layer 16 wraps around the main surface too much, the portion where the end face sealing layer 16 wraps around the main surface bulges. Accordingly, the overall smoothness of the laminated film 10 may deteriorate. Furthermore, the wrapped portion functions as a light shielding layer, and consequently, a non-light-emitting region occurs at the edge of the laminated film 10, the frame portion is enlarged, and the effectively usable region is narrowed. That is, the application of the laminated film 10 to a narrow frame module of a mobile display or the like may be hindered.

From the viewpoint described above, a wrapping width d (see FIG. 4) of the end face sealing layer 16 on the main surface of the functional layer laminate 11 is preferably equal to or smaller than 1 mm, more preferably equal to or smaller than 0.5 mm, and particularly preferably equal to or smaller than 0.1 mm at which the existence of a wrapped region is not easily visually recognized.

The wrapping width d of the end face sealing layer 16 can be measured by, for example, performing cross-section cutting on the laminated film by using RETRATOME REM-710 manufactured by YAMATO KOHKI INDUSTRIAL CO., LTD, and observing the cross-section by using an optical microscope.

As shown in FIG. 4, in a case where a cross-section of the functional layer laminate 11 is seen in a direction orthogonal to the extension direction of the end face of the functional layer laminate 11, the width of a region of the end face sealing layer 16 formed on the main surface of the functional layer laminate 11 (width of the region in a direction perpendicular to the end face of the functional layer laminate 11) is taken as the wrapping width d.

From the viewpoint of improving the gas barrier properties of the end face sealing layer 16, it is preferable the end face sealing layer 16 has a small number of pinholes. In the present invention, a pinhole means an uncoated portion having a size of equal to or greater than 1 μm (portion where the metal film is missed) that is seen in a case where the end face sealing layer 16 is observed with an optical microscope. The pinhole has any shape such as a circular shape, a polygonal shape, or a linear shape. The number of pinholes is preferably equal to or smaller than 50 pinholes/mm², more preferably equal to or smaller than 20 pinholes/mm², and particularly preferably 5 pinholes/mm². The smaller the number of pinholes, the better, and there the lower limit of the number of pinholes is not particularly limited.

From the viewpoint of forming the end face sealing layer 16 having a small number of pinholes, it is preferable that the end face of the functional layer laminate 11 on which the end face sealing layer 16 is formed is smooth. The surface roughness of the end face of the functional layer laminate 11 is preferably 0.001 μm to 10 μm, and more preferably 0.001 μm to 2 μm.

Herein, it is preferable that among the layers constituting the end face sealing layer 16, at least one layer other than the first layer 18 contacting the functional layer laminate 11 is a metal plating layer. In the laminated films shown in FIGS. 1 and 3, the outermost layer 20 farthest from the functional layer laminate 11 is a metal plating layer. In this way, it is preferable that the outermost layer 20 is a metal plating layer.

In a case where at least one layer other than the first layer 18 is a metal plating layer, the layer can be formed as a thick layer, and sufficient gas barrier properties can be exhibited.

The first layer 18 provided in a state of contacting the end face of the functional layer laminate 11 is preferably a metal layer formed by any method among a sputtering method, a vacuum vapor deposition method, an ion plating method, and a plasma CVD method, and more preferably a layer formed by a sputtering method which makes it possible to form a film having excellent adhesiveness at a low temperature.

The functional layer laminate 11 is mainly formed of a resin. Therefore, in a case where the metal plating layer is directly formed on the functional layer laminate 11 by electroplating, a metal film is not obtained because there is no electrically conducting path. Furthermore, in a case where the metal plating layer is formed by electroless plating, the adhesiveness between the functional layer laminate 11 and the metal plating layer is poor, sufficient durability and gas barrier properties cannot be obtained, and the film cannot be selectively formed only on the end face.

In contrast, in the present invention, the first layer 18 composed of a metal formed by the aforementioned method is provided on the lateral surface of the functional layer laminate 11. Therefore, the adhesiveness between the functional layer laminate 11 and the end face sealing layer 16 can be improved.

Furthermore, in a case where the first layer 18 formed of a metal is provided on the lateral surface of the functional layer laminate 11, at the time of forming a metal plating layer as a layer other than the first layer 18, the first layer functions as an electrode, and hence the metal plating layer can be appropriately formed. In addition, at the time of the plating treatment, the first layer protects the functional layer laminate 11, and hence the damage of the functional layer laminate 11 can be prevented.

In a case where the end face sealing layer is constituted only with one metal layer is formed by any method among a sputtering method, a vacuum vapor deposition method, an ion plating method, and a plasma CVD method, the adhesiveness of this layer with respect to the functional layer laminate can be improved, but it is not easy to form a thick layer. Alternatively, for forming a thick layer, the productivity becomes extremely poor. Accordingly, there is no choice but to form a thin layer. As a result, a film having a uniform thickness cannot be formed on the end face of the functional layer laminate, and sufficient gas barrier properties cannot be obtained.

In contrast, in the present invention, there are provided the first layer which is formed by any method among a sputtering method, a vacuum vapor deposition method, an ion plating method, and a plasma CVD method as well as a metal plating layer. Accordingly, the adhesiveness of the end face sealing layer with respect to the functional layer laminate can be improved, and sufficient gas barrier properties can be obtained.

It is preferable that the thickness of the metal plating layer formed as a layer other than the first layer 18 is greater than the thickness of the first layer 18 contacting the functional layer laminate 11.

In a case where the thickness of the metal plating layer is greater than the thickness of the first layer 18, sufficient gas barrier properties can be more reliably exhibited.

The thickness of the first layer 18 and the thickness of the metal plating layer refer to a thickness in a direction perpendicular to the end face of the functional layer laminate 11.

Specifically, from the viewpoint of the adhesiveness with respect to the functional layer laminate 11, the productivity, and the like, the thickness of the first layer 18 is preferably 0.001 μm to 0.5 μm, and more preferably 0.01 μm to 0.3 μm.

Furthermore, from the viewpoint of securing gas barrier properties, the productivity, and the like, the thickness of the metal plating layer is preferably 0.01 μm to 100 μm, and more preferably 1 μm to 10 μm.

The material for forming the first layer 18 contacting the functional layer laminate 11 is not particularly limited as long as the material is a metal. It is preferable that the material enables the first layer 18 to be formed by any method among a sputtering method, a vacuum vapor deposition method, an ion plating method, and a plasma CVD method described above. Furthermore, from the viewpoint of improving the adhesiveness with respect to the resin constituting the functional layer laminate 11, it is preferable to use a metal having a high ionization tendency. Accordingly, the material is preferably either at least one kind of metal selected from the group consisting of aluminum, titanium, chromium, copper, and nickel or an alloy containing at least one kind of these metals, and particularly preferably either at least one kind of metal selected from the group consisting of aluminum, titanium, and chromium or an alloy containing at least one kind of these metals. Presumably, in a case where a metal having a high ionization tendency is used, an oxygen atom, a nitrogen atom, a carbon atom, or the like constituting the resin may form a compound together with the metal, a metal oxide, a metal nitride, or a metal carbide may be easily formed in the interface between the resin and the first layer 18, and hence the adhesiveness may be improved.

In a case where the metal or alloy described above is used as the material for forming the first layer 18, the first layer 18 can be formed by any method among a sputtering method, a vacuum vapor deposition method, an ion plating method, and a plasma CVD method, and the adhesiveness between the first layer 18 and the lateral surface of the functional layer laminate 11 can be improved.

The material for forming each layer other than the first layer 18 is not particularly limited as long as the material is a metal. The material is preferably either at least one kind of metal selected from the group consisting of aluminum, titanium, chromium, nickel, tin, copper, silver, and gold or an alloy containing at least one kind of these metals.

In a case where the metal or alloy described above is used as the material for forming each layer other than the first layer 18, each layer can be formed by a plating treatment, and high gas barrier properties can be exhibited.

At least one layer other than the first layer 18 may be formed by a plating treatment. The layers other than the metal plating layer may be formed by any method among a sputtering method, a vacuum vapor deposition method, an ion plating method, and a plasma CVD method. At this time, it is preferable that at least the outermost layer 20 is formed by a plating treatment.

For example, the laminated film 10b shown in FIG. 3 has the end face sealing layer 16b in which the first layer 18 and the second layer 22 are formed by a sputtering method while the outermost layer 20 is formed by a plating treatment. However, the present invention is not limited thereto. For example, the first layer 18 may be formed by a sputtering method, the second layer 22 may be formed by a plating treatment, and the outermost layer 20 may be formed by a sputtering method.

Each of the layers constituting the end face sealing layer 16 may be formed of the same material or different materials. That is, for example, the first layer 18 may be a nickel layer formed by a sputtering method, and the outermost layer 20 may be a nickel layer formed by a plating treatment.

The laminated film 10a shown in FIG. 1 has a constitution in which three layers including the gas barrier layer 14, the optically functional layer 12, and the gas barrier layer 14 are laminated, and the end face sealing layer 16a is disposed on the end face thereof. However, the present invention is not limited thereto, and the laminated film may include other layers. For example, the laminated film may include a hardcoat layer, an optical compensation layer, a transparent conductive layer, and the like.

Next, the method for manufacturing a laminated film of the present invention (hereinafter, referred to as “manufacturing method of the present invention” as well) will be described.

The method for manufacturing a laminated film of the first aspect of the present invention is a method for manufacturing a laminated film including the end face sealing layer, which includes at least two layers and in which each of the layers included in the end face sealing layer is formed of a metal, on a lateral surface of the functional layer laminate having the optically functional layer and the gas barrier layer, the method including a first layer forming step of forming the first layer, which contacts the functional layer laminate, on an end face of a laminated material obtained by stacking a plurality of sheets of the functional layer laminate, and an outermost layer forming step of forming the outermost layer on the first layer formed on the end face of the laminated material, in which a method for forming the first layer is one kind of method selected from the group consisting of a sputtering method, a vacuum vapor deposition method, an ion plating method, and a plasma CVD method.

The method for manufacturing a laminated film of the second aspect of the present invention is a method for manufacturing a laminated film including the end face sealing layer, which includes at least two layers and in which each of the layers included in the end face sealing layer is formed of a metal, on a lateral surface of the functional layer laminate having the optically functional layer and the gas barrier layer, the method including forming the functional layer laminate, which is obtained by coating a gas barrier film having the gas barrier layer with the polymerizable composition containing phosphors and at least two or more kinds of polymerizable compounds and curing the polymerizable composition, a first layer forming step of forming the first layer, which contacts the functional layer laminate, on an end face of a laminated material obtained by stacking a plurality of sheets of the functional layer laminate, and an outermost layer forming step of forming the outermost layer on the first layer formed on the end face of the laminated material, in which a method for forming the first layer is one kind of method selected from the group consisting of a sputtering method, a vacuum vapor deposition method, an ion plating method, and a plasma CVD method.

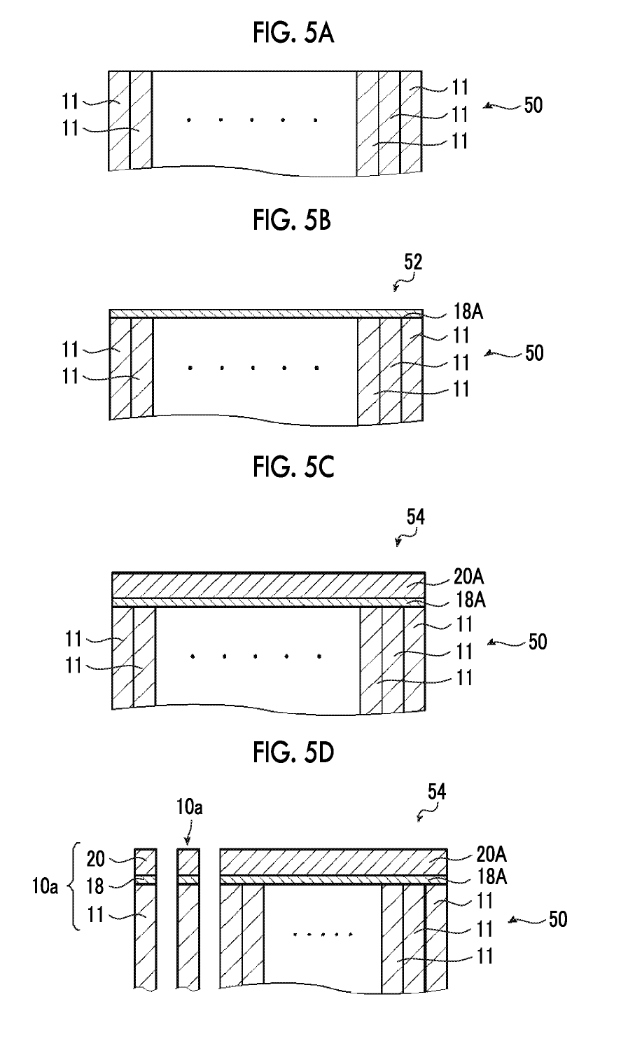

In a preferred aspect of the manufacturing method of the present invention, a method for forming at least one layer included in the end face sealing layer other than the first layer is a metal plating treatment. Hereinafter, by using FIGS. 5A to 5D, an example of the manufacturing method of the present invention will be described.

First, the functional layer laminate 11 is prepared which includes the optically functional layer 12 and two gas barrier layers 14 laminated on both the main surfaces of the optically functional layer 12.

As described above, for example, the functional layer laminate 11 can be prepared by a method in which a coating composition is prepared by mixing quantum dots with a resin, which will become a matrix, and a solvent; coating a gas barrier film 14 with the coating composition and curing the composition such that the optically functional layer 12 (quantum dot layer) is formed, and the other gas barrier film 14 is formed by being laminated on the other main surface of the formed optically functional layer 12.

In the present invention, the gas barrier layer may be laminated on at least one main surface of the optically functional layer. In a case where the laminated film of the present invention having the aforementioned constitution is finally assembled with a backlight unit of LCD or the like together with other members, because the other main surface is protected from the permeation of oxygen or moisture, the deterioration of the performance of the functional layer can be prevented.

The functional layer laminate 11 may be prepared by a so-called single-type method in which the functional layer laminate 11 is prepared one by one. Alternatively, the functional layer laminate 11 may be prepared by a so-called roll-to-roll (hereinafter, referred to as RtoR as well) method of continuously preparing the functional layer laminate 11, in which while a long gas barrier film 14 is being transported in a longitudinal direction, the optically functional layer 12 is formed on the gas barrier film 14, and another gas barrier film is also laminated on the formed optically functional layer.

If necessary, the manufacturing method of the present invention may include a step of cutting the prepared functional layer laminate 11 in a desired size.

The method for cutting the functional layer laminate 11 is not limited, and it is possible to use various known methods such as a method of physically cutting the functional layer laminate by using a blade such as a Thomson blade and a method for cutting the functional layer laminate by irradiating the laminate with laser.

In a case where the functional layer laminate is cut by laser cutting, the surface roughness of the end face of the functional layer laminate 11 can be reduced.

Furthermore, after the functional layer laminate 11 is processed in a predetermined shape, polishing processing for controlling the surface roughness of the end face may be performed. For example, after the functional layer laminate is cut using a blade, by performing a cutting treatment, a polishing treatment, or a melting treatment on the end face, the surface roughness can be controlled.

Specifically, for example, by performing end face cutting on the cut functional layer laminate 11 by using RETRATOME REM-710 manufactured by YAMATO KOHKI INDUSTRIAL CO., LTD or the like, the surface roughness can be controlled. More specifically, as the angle at which the cutting blade is brought into contact with the functional layer laminate 11, that is, as the angle formed between the movement direction of the blade and the blade face becomes close to a right angle, the smoothness is improved. The angle at which the cutting blade is brought into contact with the functional layer laminate 11 is preferably within a range of 70° to 110°, more preferably within a range of 80° to 100°, and even more preferably within a range of 85° to 95°. Conventionally, the angle formed between a direction orthogonal to the movement direction of the blade and the blade face is called “blade edge angle” in some cases. In addition, the surface roughness can also be controlled by appropriately controlling the width of a portion removed by cutting (cutting depth). The cutting depth is preferably within a range of 1 to 20 μm, and more preferably within a range of 5 to 15 μm. Presumably, the change in the surface roughness according to the cutting condition may result from the shaking of the cut surface caused by the distortion or twisting of the functional layer laminate 11 that occurs in a case where the cutting blade is brought into contact with the functional layer laminate 11. Therefore, it is preferable to appropriately set the condition according to the balance between the hardness, brittleness, and viscosity of the functional layer laminate 11 used.

The cutting residue generated at the time of cutting causes problems in the first layer forming step or the outermost layer forming step following cutting. Therefore, after cutting, it is preferable to remove the cutting residue as soon as possible. Examples of the step of removing the cutting residue include ultrasonic cleaning performed in a state where the functional layer laminate is sprayed with air or immersed in a cleaning solution, a method using bonding and peeling of a pressure sensitive adhesive sheet, a wiping method, and the like.

Then, as the first layer forming step, a laminated material 50 (see FIG. 5A) is prepared by stacking a plurality of sheets of the prepared functional layer laminate 11, and a first layer 18A (see FIG. 5B) is formed on the end face of the laminated material 50.

As described above, as the method for forming the first layer 18A, any method among a sputtering method, a vacuum vapor deposition method, an ion plating method, electroless plating, and a plasma CVD method may be used. As the first layer 18A, a layer formed of at least one kind of metal selected from the group consisting of aluminum, titanium, chromium, copper, and nickel or formed of an alloy containing at least one kind of these metals is formed on the end face of the laminated material 50.

The treatment method, the treatment conditions, and the like in a sputtering method, a vacuum vapor deposition method, an ion plating method, electroless plating, and a plasma CVD method used at the time of forming the first layer 18A are not particularly limited. The first layer 18A may be formed by using a treatment method and treatment conditions known in the related art according to the material for forming the first layer 18A and the like.

In a region of the functional layer laminate 11 other than the end face, that is, in a region where the first layer 18A is not formed, a masking treatment or the like may be formed by a known method such that the first layer 18A is formed on the end face of the functional layer laminate 11.

At the time of forming the first layer 18A, the number of sheets of the functional layer laminate 11 in the laminated material 50 is not particularly limited, and may be appropriately set according to the size of a device forming the first layer 18A, the thickness of the functional layer laminate 11, and the like. It is preferable to form the first layer 18A by stacking 500 to 4,000 sheets of the functional layer laminate 11.

Then, as the outermost layer forming step, an outermost layer 20A is formed on the first layer 18A of a laminated material 52 in which the first layer 18A is formed on the end face thereof (FIG. 5C).

As described above, as the method for forming the outermost layer 20A, a plating treatment is preferable. As the outermost layer 20A, a layer formed of at least one kind of metal selected from the group consisting of aluminum, titanium, chromium, nickel, tin, copper, silver, and gold or formed of an alloy containing at least one kind of these metals is formed on the first layer 18A of the laminated material 52.

The treatment method, the treatment condition, and the like of the plating treatment used at the time of forming the outermost layer 20A are not particularly limited. The outermost layer 20A may be formed by using a treatment method and treatment conditions known in the related art according to the material for forming the outermost layer 20A, and the like.

Thereafter, a laminated material 54 in which the outermost layer 20A is formed is separated for each of the functional layer laminates 11. In this way, the functional layer laminate 11 in which the end face sealing layer 16a is formed on the end face thereof, that is, the laminated film 10a can be obtained (FIG. 5D).

The method for separating the laminated film 10a from the laminated material 54 is not particularly limited. The laminated film 10a can be separated by a method of shearing the laminated material 54, in which the outermost layer 20A is formed, by applying external force in a direction horizontal to the surface of the laminated material 54 by means of bending, twisting, or the like, or a method of sticking a sharp tip of, for example, a blade into the interface of the functional layer laminate 11.

From the viewpoint of preventing the occurrence of peeling, missing, or cracking of the end face sealing layer, it is preferable to separate the laminated film 10a by means of shearing using an external force.

As described above, in the manufacturing method of the present invention, at the time of forming the respective layers of the end face sealing layer 16, it is possible to form the respective layers of the end face sealing layer 16 in a state where a plurality of sheets of the functional layer laminates 11 are stacked. Accordingly, a plurality of laminated films 10 can be collectively prepared, and hence the productivity can be improved.

The surface roughness Ra of the end face of the functional layer laminate 11 is preferably equal to or lower than 2.0 μm. In a case where the surface roughness Ra of the end face of the functional layer laminate 11 is equal to or lower than 2.0 μm, the adhesiveness between the functional layer laminate 11 and the first layer 18 formed on the end face can be further improved.

In the above section, as an example, a manufacturing method was described which is used in a case where the laminated film 10a including two end face sealing layers 16 is prepared. In a case where the laminated film includes three or more end face sealing layers 16, the manufacturing method may include a step of forming the second layers and the following layers between the first layer forming step and the outermost layer forming step.

The second layer and the following layers can be formed by the same method as the formation method in the aforementioned first layer forming step or by the same method as the formation method in the outermost layer forming step, except that a different layer is used as a base.

In the manufacturing method of the present invention, in order to inhibit the corrosion of the end face sealing layer 16 formed of a metal, a rust proofing treatment or the like may be performed.

Hitherto, the laminated film and the manufacturing method thereof of the present invention have been specifically described, but the present invention is not limited to the above embodiments. It goes without saying that the present invention may be ameliorated or modified in various ways within a scope that does not depart from the gist of the present invention.

### EXAMPLES

Hereinafter, the present invention will be more specifically described based on specific examples of the present invention. The present invention is not limited to the examples described below, and the materials, the amount and proportion of the materials used, the treatment content, the treatment sequence, and the like shown in the following examples can be appropriately modified as long as the modification does not depart from the gist of the present invention.

### Example 1

For the laminated film of the second aspect of the present invention, the laminated film 10b shown in FIG. 3 was prepared as Example 1.

<Preparation of Gas Barrier Film>

(Gas Barrier Support)

As the gas barrier film 14, a gas barrier film was used in which the organic layer 34, the inorganic layer 36, and the organic layer 38 were formed in this order on the gas barrier support 30.

As the gas barrier support 30, a polyethylene terephthalate film (PET film, manufactured by Toyobo Co., Ltd, trade name: COSMOSHINE A4300, thickness: 50 μmm, width: 1,000 mm, length: 100 m) was used.

(Formation of First Organic Layer)

The organic layer (hereinafter, referred to as a first organic layer as well) 34 was formed on one main surface of the gas barrier support 30.

First, a coating solution for forming the first organic layer (coating solution for forming a first organic layer) was prepared as below.

Trimethylolpropane triacrylate (TMPTA, manufactured by Daicel SciTech) and a photopolymerization initiator (manufactured by Lamberti S.p.A, ESACURE KTO46) were prepared, weighed such that a weight ratio of TMPTA:photopolymerization initiator became 95:5, and dissolved in methyl ethyl ketone, thereby preparing a coating solution with a concentration of solid contents of 15%.

By using a die coater, the gas barrier support 30 was coated with the coating solution for forming a first organic layer by a roll-to-roll method. The gas barrier support 30 having undergone coating was passed through a drying zone with a temperature of 50° C. for 3 minutes and then irradiated with ultraviolet rays (cumulative irradiation amount: about 600 mJ/cm²) such that the coating solution was cured by UV curing. As a protective film, a polyethylene film (PE film, manufactured by Sun A Kaken Co., Ltd., trade name: PAC 2-30-T) was bonded to the pass roll immediately after the UV curing, and the resulting film was transported and wound up. The thickness of the first organic layer 34 formed on the gas barrier support 30 was 1 μm.

(Formation of Inorganic Layer)

Then, by using a general RtoR CVD device, the inorganic layer 36 having a thickness of 50 nm was formed on the first organic layer 34 by CCP-CVD.

Specifically, the laminate obtained by forming the first organic layer 34 on the gas barrier support 30 and bonding a protective film onto the first organic layer 34 was fed from a feeding machine, and before an inorganic layer was formed, the protective film was peeled off after the laminate passed the last film surface-touching roll. Then, on the exposed first organic layer 34, the inorganic layer 36 was formed.

As raw material gases, silane gas (SiH₄), ammonia gas (NH₃), nitrogen gas (N₂), and hydrogen gas (H₂) were used. The amount of silane gas supplied was 160 sccm, the amount of ammonia gas supplied was 370 sccm, the amount of nitrogen gas supplied was 240 sccm, and the amount of hydrogen gas supplied was 590 sccm. The film forming pressure was 40 Pa. That is, the inorganic layer 36 was a silicon nitride film. The plasma excitation power was 2.5 kW at a frequency of 13.56 MHz.

(Formation of Second Organic Layer)

Then, on the surface of the formed inorganic layer 36, the organic layer 38 (hereinafter, referred to as a second organic layer) protecting the inorganic layer was formed.

First, a coating solution for forming the second organic layer (coating solution for forming a second organic layer) was prepared as below.

A urethane bond-containing acryl polymer (ACRIT 8BR500 manufactured by TAISEI FINE CHEMICAL CO., LTD., weight-average molecular weight: 250,000) and a photopolymerization initiator (IRGACURE 184 manufactured by BASF SE) were weighed such that a mass ratio of acryl polymer:photopolymerization initiator became 95:5, and dissolved in methyl ethyl ketone, thereby preparing a coating solution with a concentration of solid contents of 15% by mass.

By using a die coater, the surface of the inorganic layer 36 was coated with the prepared coating solution for forming a second organic layer by a roll-to-roll method, and the resulting film was passed through a drying zone with a temperature of 100° C. for 3 minutes and wound up. The thickness of the second organic layer formed in this way was 1 μm.

Immediately after the second organic layer was formed, a protective PE film was bonded thereto by a film surface-touching roll portion. The resulting film was transported with preventing the second organic layer from contacting the pass roll and then wound up.

In the manner described above, the gas barrier film 14 was prepared in which the first organic layer 34, the inorganic layer 36, and the second organic layer 38 were laminated in this order on the gas barrier support 30.

As a result of measuring the oxygen permeability of the prepared gas barrier film 14 by an APIMS method, the oxygen permeability at a temperature of 25° C. and a humidity of 60% RH was 1×10⁻³ [cc/(m²-day·atm)].

<Preparation of Functional Layer Laminate>

(Formation of Optically Functional Layer)

Thereafter, the protective PE film was peeled off, and then a coating film was formed by coating the second organic layer 38 of the gas barrier film 14 with a coating solution for forming the optically functional layer 12 (coating solution for forming an optically functional layer). Subsequently, the gas barrier film 14 prepared as described above was laminated on the coating film, and the coating film was sandwiched between the gas barrier films 14 in a nitrogen atmosphere and then cured by being irradiated with UV in a nitrogen atmosphere, thereby forming the optically functional layer 12.

(Composition of Coating Solution for Forming Optically Functional Layer)

| | | |
|---|---|---|
| Toluene dispersion liquid of quantum dot 1 | 10 | parts by mass |
| (emission maximum: 520 nm) | | |
| Toluene dispersion liquid of quantum dot 2 | 1 | part by mass |
| (emission maximum: 630 nm) | | |
| Lauryl acrylate | 2.4 | parts by mass |
| 1,9-Nonanediol diacrylate | 0.54 | parts by mass |
| Photopolymerization initiator (IRGACURE 819 | 0.003 | parts by mass |
| (manufactured by BASF SE)) | | |

As the quantum dots 1 and 2, the following nanocrystals having a core-shell structure (InP/ZnS) were used.
Quantum dot 1: INP 530-10 (manufactured by NN-LABS, LLC)
Quantum dot 2: INP 620-10 (manufactured by NN-LABS, LLC)

The viscosity of the coating solution for forming an optically functional layer was 50 mPa·s.

(Sheet Processing)

By using a Thomson blade with a blade edge angle of 17°, the laminate of two gas barrier films 14 and the optically functional layer 12 was punched in the form of a sheet with A4 size, thereby obtaining the functional layer laminate 11.

<Formation of End Face Sealing Layer>

(Formation of First Layer)

1,000 sheets of functional layer laminates 11 cut in the form of a sheet were stacked, and by using a general sputtering machine, the first layer 18A was formed on the lateral surface of the laminated material 50 obtained by stacking a plurality of sheets of the functional layer laminates 11. Titanium was used as a target, and argon was used as a discharge gas. The film forming pressure was 0.5 Pa, the film forming power was 400 W, and the film thickness reached 10 nm.

(Formation of Second Layer)

Then, a second layer having a film thickness of 75 nm was formed on the first layer 18A in the same manner as in Formation of first layer, except that the target was changed to copper from titanium.

(Formation of Outermost Layer)

Then, the outermost layer 20A was formed on the second layer as below.

First, the laminated material, in which the first layer 18A and the second layer were formed, was washed with pure water and degreased by being immersed in a bath filled with a commercially available surfactant for 20 seconds. Thereafter, the laminated material was washed water, then subjected to an acid activation treatment by being immersed in a 5% aqueous sulfuric acid solution for 5 seconds, and washed again with water.

The laminated material washed with water was fixed to a plating jig, and by using a tester, whether electricity was conducted was checked. Subsequently, the laminated material was subjected to an acid activation treatment by being immersed in a 5% aqueous nitric acid solution for 10 seconds and then subjected to an electroplating treatment for 5 minutes by using a copper sulfate bath under the condition of a current density of 3.0 A/dm², thereby forming an outermost layer as a metal plating layer on the second layer. Then, the laminated material was washed with water and subjected to a rust-proofing treatment, and the surplus moisture was removed using air, thereby obtaining a laminated material in which a metal layer constituted with three layers was formed on the end face.

(Separation Step)

Thereafter, by applying an external force in a direction horizontal to the surface of the functional layer laminates 11, the laminated material in which the metal layer constituted with three layers was formed on the end face thereof was sheared such that the laminated material was separated for each of the functional layer laminates 11, thereby obtaining the functional layer laminate 11 in which the end face sealing layer 16b was formed on the end face thereof, that is, the laminated film 10b.

### Examples 2 to 22 and Comparative Examples 1 to 4

The laminated film 10b was prepared in the same manner as in Example 1, except that the material and the film thickness of each of the first layer 18, the second layer 22, and the outermost layer 20 as well as the surface roughness Ra of the end face of the functional layer laminate 11 were changed as shown in the following Table 1 (Table 1-1 to Table 1-6).

### Example 23

The laminated film 10b was prepared in the same manner as in Example 19, except that the toluene dispersion liquids of the quantum dot 1 and the quantum dot 2 in the coating solution for forming an optically functional layer were changed to toluene dispersion liquids of a quantum dot 3 (CZ520-10, manufactured by NN-LABS, LLC) and a quantum dot 4 (CZ620-10, manufactured by NN-LABS, LLC).

[Evaluation]

<Evaluation of End Face Sealing Performance>

The prepared laminated films of Examples 1 to 23 and Comparative Examples 1 to 4 were tested as below, and the end face sealing performance thereof was evaluated.

First, an initial luminance (Y0) of a single sheet of the separated laminated film was measured according to the following sequence. A commercially available tablet terminal (Kindle (registered trademark) Fire HDX 7″ manufactured by Amazon.com, Inc) was disassembled, and the backlight unit was taken out. The laminated film was disposed on the light guide plate of the backlight unit taken out, and two prism sheets having directions orthogonal to each other were stacked on the laminated film. The luminance of light, which was emitted from a blue light source and transmitted through the laminated film and two prism sheets, was measured using a luminance meter (SR3, manufactured by TOPCON CORPORATION) installed in a position 740 mm distant from light guide plate in a direction perpendicular to the surface of the light guide plate, and taken as the luminance of the laminated film.

Then, the laminated film was put into a constant-temperature tank kept at 60° C. and a relative humidity of 90% and stored as it was for 1,000 hours. After 1,000 hours, the laminated film was taken out, and a luminance (Y1) after the high-temperature high-humidity testing was measured according to the same sequence as described above. By using the following equation, a rate of change (ΔY) of the luminance (Y1) after the high-temperature high-humidity testing with respect to the initial luminance (Y0) was calculated. By using ΔY as a parameter of a luminance change, the end face sealing performance was evaluated based on the following standards.

ΔY[%]=(Y0−Y1)/Y0×100

In a case where the evaluation result is C or better, it is possible to make a judgment that the emission efficiency of the edge is excellently maintained even after the high-temperature and high-humidity testing.

A: ΔY≤5%

B: 5%<ΔY<10%

C: 10%≤ΔY<15%

D: 15%≤ΔY

<Evaluation of Adhesiveness>

By using a sample which was not yet being subjected to the separation step and was in a state where the end face sealing layer was formed on the end face of the laminated material of a plurality of sheets of functional layer laminates, a 100-square crosscut test (based on JIS D0202-1988) was performed. Based on the number of squares that were not peeled, the adhesiveness between the end face of the functional layer laminate and the end face sealing layer was evaluated.

The evaluation standards of the adhesiveness are as below. A to C are passing grades, and D is a failing grade.

A: 100

B: equal to or greater than 95 and equal to or smaller than 99

C: equal to or greater than 90 and equal to or smaller than 94

D: less than 90

<Measurement of Modulus of Elasticity>

Based on the makeup of the polymerizable composition containing quantum dots used in each of the examples and the comparative examples, a composition for preparing a model film was prepared from which the toluene dispersion liquids of the quantum dot 1 and the quantum dot 2 were excluded, and a model film having a thickness of 60 μm was prepared. Specifically, the model film was prepared by the following method.

By using a wire bar, a peeling film (LUMIRROR #50 manufactured by TORAY INDUSTRIES, INC., thickness: 50 μm) was coated with the composition for preparing a model film, and another sheet of peeling film was laminated thereon. By using an air-cooled metal halide lamp (manufactured by EYE GRAPHICS Co., Ltd.) at 200 W/cm, the coated surface was irradiated with ultraviolet rays at 1,000 mJ/cm² such that the film was cured. All of the aforementioned steps were performed in a nitrogen atmosphere. The model film was cut in 5 mm×30 mm, and the peeling film on both surfaces of the cured film obtained in this way was peeled, thereby obtaining a single film (model film) having only a resin layer with a thickness of 60 μm.

The model film was humidified for 2 or more hours at 25° C. and 60% RH. Then, by using a dynamic viscoelasticity measurement apparatus (VIBRON: DVA-225 (manufactured by A&D Company, Limited)), the viscoelasticity of the model film was measured under the condition of a gripping distance of 20 mm, a heating rate of 2° C./min, a range of a measurement temperature of 30° C. to 150° C., and a frequency of 1 Hz. The value of a storage elastic modulus at 50° C. was used as a modulus of elasticity.

The results are shown in the following Table 1 (Table 1-1 to Table 1-6).

TABLE 1-1

| | | | Example 1 | Example 2 | Example 3 | Example 4 | Example 5 |
|---|---|---|---|---|---|---|---|
| Optically functional | | Quantum dot 1 | Toluene | Toluene | Toluene | Toluene | Toluene |
| layer | | | dispersion liquid | dispersion liquid | dispersion liquid | dispersion liquid | dispersion liquid |
| | | | of quantum dot 1 | of quantum dot 1 | of quantum dot 1 | of quantum dot 1 | of quantum dot 1 |
| | | Amount (part by mass) | 10 | 10 | 10 | 10 | 10 |
| | | Quantum dot 2 | Toluene | Toluene | Toluene | Toluene | Toluene |
| | | | dispersion liquid | dispersion liquid | dispersion liquid | dispersion liquid | dispersion liquid |
| | | | of quantum dot 2 | of quantum dot 2 | of quantum dot 2 | of quantum dot 2 | of quantum dot 2 |
| | | Amount (part by mass) | 1 | 1 | 1 | 1 | 1 |
| | | First polymerizable | Lauryl acrylate | Lauryl acrylate | Dicyclopentanyl | Dicyclopentanyl | Isobornyl acrylate |
| | | composition | | | acrylate | acrylate | |
| | | Amount (part by mass) | 2.4 | 1.47 | 2.4 | 1.47 | 2.4 |
| | | Second polymerizable | 1.9NDA | 1.9NDA | 1.9NDA | 1.9NDA | 1.9NDA |
| | | composition | | | | | |
| | | Amount (part by mass) | 0.54 | 1.47 | 0.54 | 1.47 | 0.54 |
| | | Photopolymerization | Irg819 | Irg819 | Irg819 | Irg819 | Irg819 |
| | | initiator | | | | | |
| | | Amount (part by mass) | 0.003 | 0.003 | 0.003 | 0.003 | 0.003 |
| Substrates | | Barrier film | Barrier film 14 | Barrier film 14 | Barrier film 14 | Barrier film 14 | Barrier film 14 |
| End face | First | Material | Ti | Ti | Ti | Ti | Ti |
| sealing layer | Layer | Film thickness [μm] | 0.01 | 0.01 | 0.01 | 0.01 | 0.01 |
| | | Film forming method | Sputtering | Sputtering | Sputtering | Sputtering | Sputtering |
| | Second | Material | Cu | Cu | Cu | Cu | Cu |
| | layer | Film thickness [μm] | 0.2 | 0.2 | 0.2 | 0.2 | 0.2 |
| | | Film forming method | Sputtering | Sputtering | Sputtering | Sputtering | Sputtering |
| | Third | Material | Cu | Cu | Cu | Cu | Cu |
| | layer | Film thickness [μm] | 5 | 5 | 5 | 5 | 5 |
| | | Film forming method | Electroplating | Electroplating | Electroplating | Electroplating | Electroplating |

| Evaluation | Modulus of elasticity at | 15 | 48 | 18 | 55 | 32 |
|---|---|---|---|---|---|---|
| | 50° C. [MPa] | | | | | |
| | Sealing performance | A | B | A | B | A |
| | Adhesiveness | A | A | A | A | A |

| Reagent list | Detail | Maker |
|---|---|---|
| Lauryl acrylate | Aliphatic monofunctional (meth)acrylate compound | Manufactured by TOKYO CHEMICAL INDUSTRY CO., LTD. |
| Dicyclopentanyl acrylate | Aliphatic monofunctional (meth)acrylate compound | Manufactured by TOKYO CHEMICAL INDUSTRY CO., LTD. |
| Isobornyl acrylate | Aliphatic monofunctional (meth)acrylate compound | Manufactured by TOKYO CHEMICAL INDUSTRY CO., LTD. |
| 1,9 NDA | Difunctional (meth)acrylate compound | Manufactured by SHIN-NAKAMURA CHEMICAL CO., LTD. |

TABLE 1-2

| | | | Example 6 | Example 7 | Example 8 | Example 9 | Example 10 |
|---|---|---|---|---|---|---|---|
| Optically functional | | Quantum dot 1 | Toluene | Toluene | Toluene | Toluene | Toluene |
| layer | | | dispersion liquid | dispersion liquid | dispersion liquid | dispersion liquid | dispersion liquid |
| | | | of quantum dot 1 | of quantum dot 1 | of quantum dot 1 | of quantum dot 1 | of quantum dot 1 |
| | | Amount (part by mass) | 10 | 10 | 10 | 10 | 10 |
| | | Quantum dot 2 | Toluene | Toluene | Toluene | Toluene | Toluene |
| | | | dispersion liquid | dispersion liquid | dispersion liquid | dispersion liquid | dispersion liquid |
| | | | of quantum dot 2 | of quantum dot 2 | of quantum dot 2 | of quantum dot 2 | of quantum dot 2 |
| | | Amount (part by mass) | 1 | 1 | 1 | 1 | 1 |
| | | First polymerizable | Isobornyl acrylate | Benzyl acrylate | Benzyl acrylate | Lauryl acrylate | Lauryl acrylate |
| | | composition | | | | | |
| | | Amount (part by mass) | 1.47 | 2.4 | 1.47 | 2.4 | 1.47 |
| | | Second polymerizable | 1.9NDA | 1.9NDA | 1.9NDA | A-DCP | A-DCP |
| | | composition | | | | | |
| | | Amount (part by mass) | 1.47 | 0.54 | 1.47 | 0.54 | 1.47 |
| | | Photopolymerization | Irg819 | Irg819 | Irg819 | Irg819 | Irg819 |
| | | initiator | | | | | |
| | | Amount (part by mass) | 0.003 | 0.003 | 0.003 | 0.003 | 0.003 |
| Substrates | | Barrier film | Barrier film 14 | Barrier film 14 | Barrier film 14 | Barrier film 14 | Barrier film 14 |
| End face | First | Material | Ti | Ti | Ti | Ti | Ti |
| sealing layer | Layer | Film thickness [μm] | 0.01 | 0.01 | 0.01 | 0.01 | 0.01 |
| | | Film forming method | Sputtering | Sputtering | Sputtering | Sputtering | Sputtering |
| | Second | Material | Cu | Cu | Cu | Cu | Cu |
| | layer | Film thickness [μm] | 0.2 | 0.2 | 0.2 | 0.2 | 0.2 |
| | | Film forming method | Sputtering | Sputtering | Sputtering | Sputtering | Sputtering |
| | Third | Material | Cu | Cu | Cu | Cu | Cu |
| | layer | Film thickness [μm] | 5 | 5 | 5 | 5 | 5 |
| | | Film forming method | Electroplating | Electroplating | Electroplating | Electroplating | Electroplating |

| Evaluation | Modulus of elasticity at | 75 | 16 | 49 | 180 | 460 |
|---|---|---|---|---|---|---|
| | 50° C. [MPa] | | | | | |
| | Sealing performance | B | A | B | A | B |
| | Adhesiveness | A | A | A | A | A |

| Reagent list | Detail | Maker |
|---|---|---|
| Lauryl acrylate | Aliphatic monofunctional (meth)acrylate compound | Manufactured by TOKYO CHEMICAL INDUSTRY CO., LTD. |
| Benzyl acrylate | Aromatic monofunctional (meth)acrylate compound | Manufactured by TOKYO CHEMICAL INDUSTRY CO., LTD. |
| Isobornyl acrylate | Aliphatic monofunctional (meth)acrylate compound | Manufactured by TOKYO CHEMICAL INDUSTRY CO., LTD. |
| 1,9 NDA | Difunctional (meth)acrylate compound | Manufactured by SHIN-NAKAMURA CHEMICAL CO., LTD. |
| A-DCP | Difunctional (meth)acrylate compound | Manufactured by SHIN-NAKAMURA CHEMICAL CO., LTD. |

TABLE 1-3

| | | | Example 11 | Example 12 | Example 13 | Example 14 | Example 15 |
|---|---|---|---|---|---|---|---|
| Optically functional | | Quantum dot 1 | Toluene | Toluene | Toluene | Toluene | Toluene |
| layer | | | dispersion liquid | dispersion liquid | dispersion liquid | dispersion liquid | dispersion liquid |
| | | | of quantum dot 1 | of quantum dot 1 | of quantum dot 1 | of quantum dot 1 | of quantum dot 1 |
| | | Amount (part by mass) | 10 | 10 | 10 | 10 | 10 |
| | | Quantum dot 2 | Toluene | Toluene | Toluene | Toluene | Toluene |
| | | | dispersion liquid | dispersion liquid | dispersion liquid | dispersion liquid | dispersion liquid |
| | | | of quantum dot 2 | of quantum dot 2 | of quantum dot 2 | of quantum dot 2 | of quantum dot 2 |
| | | Amount (part by mass) | 1 | 1 | 1 | 1 | 1 |
| | | First polymerizable | Lauryl acrylate | Lauryl acrylate | Lauryl acrylate | Lauryl acrylate | Lauryl acrylate |
| | | composition | | | | | |
| | | Amount (part by mass) | 2.4 | 1.47 | 2.4 | 1.47 | 2.4 |
| | | Second polymerizable | ABE-300 | ABE-300 | TMPTA | TMPTA | A-TMMT |
| | | composition | | | | | |
| | | Amount (part by mass) | 0.54 | 1.47 | 0.54 | 1.47 | 0.54 |
| | | Photopolymerization | Irg819 | Irg819 | Irg819 | Irg819 | Irg819 |
| | | initiator | | | | | |
| | | Amount (part by mass) | 0.003 | 0.003 | 0.003 | 0.003 | 0.003 |
| Substrates | | Barrier film | Barrier film 14 | Barrier film 14 | Barrier film 14 | Barrier film 14 | Barrier film 14 |
| End face | First | Material | Ti | Ti | Ti | Ti | Ti |
| sealing layer | Layer | Film thickness [μm] | 0.01 | 0.01 | 0.01 | 0.01 | 0.01 |
| | | Film forming method | Sputtering | Sputtering | Sputtering | Sputtering | Sputtering |
| | Second | Material | Cu | Cu | Cu | Cu | Cu |
| | layer | Film thickness [μm] | 0.2 | 0.2 | 0.2 | 0.2 | 0.2 |
| | | Film forming method | Sputtering | Sputtering | Sputtering | Sputtering | Sputtering |
| | Third | Material | Cu | Cu | Cu | Cu | Cu |
| | layer | Film thickness [μm] | 5 | 5 | 5 | 5 | 5 |
| | | Film forming method | Electroplating | Electroplating | Electroplating | Electroplating | Electroplating |

| Evaluation | Modulus of elasticity at | 210 | 590 | 650 | 1400 | 820 |
|---|---|---|---|---|---|---|
| | 50° C. [MPa] | | | | | |
| | Sealing performance | A | B | B | B | B |
| | Adhesiveness | A | A | B | B | B |

| Reagent list | Detail | Maker |
|---|---|---|
| Lauryl acrylate | Aliphatic monofunctional (meth)acrylate compound | Manufactured by TOKYO CHEMICAL INDUSTRY CO., LTD. |
| ABE-300 | Difunctional (meth)acrylate compound | Manufactured by SHIN-NAKAMURA CHEMICAL CO., LTD. |
| TMPTA | Trifunctional (meth)acrylate compound | Manufactured by Daicel SciTech |
| A-TMMT | Tetrafunctional (meth)acrylate compound | Manufactured by SHIN-NAKAMURA CHEMICAL CO., LTD. |

TABLE 1-4

| | | | Example 16 | Example 17 | Example 18 | Example 19 | Example 20 |
|---|---|---|---|---|---|---|---|
| Optically functional | | Quantum dot 1 | Toluene | Toluene | Toluene | Toluene | Toluene |
| layer | | | dispersion liquid | dispersion liquid | dispersion liquid | dispersion liquid | dispersion liquid |
| | | | of quantum dot 1 | of quantum dot 1 | of quantum dot 1 | of quantum dot 1 | of quantum dot 1 |
| | | Amount (part by mass) | 10 | 10 | 10 | 10 | 10 |
| | | Quantum dot 2 | Toluene | Toluene | Toluene | Toluene | Toluene |
| | | | dispersion liquid | dispersion liquid | dispersion liquid | dispersion liquid | dispersion liquid |
| | | | of quantum dot 2 | of quantum dot 2 | of quantum dot 2 | of quantum dot 2 | of quantum dot 2 |
| | | Amount (part by mass) | 1 | 1 | 1 | 1 | 1 |
| | | First polymerizable | Lauryl acrylate | Lauryl acrylate | Lauryl acrylate | Dicyclopentanyl | Dicyclopentanyl |
| | | composition | | | | acrylate | acrylate |
| | | Amount (part by mass) | 1.47 | 2.4 | 1.47 | 2.4 | 2.4 |
| | | Second polymerizable | A-TMMT | DPHA | DPHA | 1.9NDA | 1.9NDA |
| | | composition | | | | | |
| | | Amount (part by mass) | 1.47 | 0.54 | 1.47 | 0.54 | 0.54 |
| | | Photopolymerization | Irg819 | Irg819 | Irg819 | Irg819 | Irg819 |
| | | initiator | | | | | |
| | | Amount (part by mass) | 0.003 | 0.003 | 0.003 | 0.003 | 0.003 |
| Substrate | | Barrier film | Barrier film 14 | Barrier film 14 | Barrier film 14 | Barrier film 14 | Barrier film 14 |
| End face | First | Material | Ti | Ti | Ti | Ti | Ti |
| sealing layer | Layer | Film thickness [μm] | 0.01 | 0.01 | 0.01 | 0.01 | 0.01 |
| | | Film forming method | Sputtering | Sputtering | Sputtering | Sputtering | Sputtering |
| | Second | Material | Cu | Cu | Cu | Cu | Cu |
| | layer | Film thickness [μm] | 0.2 | 0.2 | 0.2 | 0.2 | 0.075 |
| | | Film forming method | Sputtering | Sputtering | Sputtering | Sputtering | Sputtering |
| | Third | Material | Cu | Cu | Cu | Cu | Cu |
| | layer | Film thickness [μm] | 5 | 5 | 5 | 5 | 5 |
| | | Film forming method | Electroplating | Electroplating | Electroplating | Electroplating | Electroplating |

| Evaluation | Modulus of elasticity at | 2100 | 1050 | 2400 | 18 | 18 |
|---|---|---|---|---|---|---|
| | 50° C. [MPa] | | | | | |
| | Sealing performance | C | C | C | A | A |
| | Adhesiveness | B | B | B | A | A |

| Reagent list | Detail | Maker |
|---|---|---|
| Lauryl acrylate | Aliphatic monofunctional (meth)acrylate compound | Manufactured by TOKYO CHEMICAL INDUSTRY CO., LTD. |
| Dicyclopentanyl acrylate | Aliphatic monofunctional (meth)acrylate compound | Manufactured by TOKYO CHEMICAL INDUSTRY CO., LTD. |
| 1,9 NDA | Difunctional (meth)acrylate compound | Manufactured by SHIN-NAKAMURA CHEMICAL CO., LTD. |
| A-TMMT | Tetrafunctional (meth)acrylate compound | Manufactured by SHIN-NAKAMURA CHEMICAL CO., LTD. |
| DPHA | Hexafunctional (meth)acrylate compound | Manufactured by SHIN-NAKAMURA CHEMICAL CO., LTD. |

TABLE 1-5

| | | | Example 21 | Example 22 | Example 23 |
|---|---|---|---|---|---|
| Optically | | Quantum dot 1 | Toluene dispersion liquid | Toluene dispersion liquid | Toluene dispersion liquid |
| functional | | | of quantum dot 1 | of quantum dot 1 | of quantum dot 3 |
| layer | | Amount (part by mass) | 10 | 10 | 10 |
| | | Quantum dot 2 | Toluene dispersion liquid | Toluene dispersion liquid | Toluene dispersion liquid |
| | | | of quantum dot 2 | of quantum dot 2 | of quantum dot 4 |
| | | Amount (part by mass) | 1 | 1 | 1 |
| | | First polymerizable | Dicyclopentanyl acrylate | Dicyclopentanyl acrylate | Dicyclopentanyl acrylate |
| | | composition | | | |
| | | Amount (part by mass) | 2.4 | 2.4 | 2.4 |
| | | Second polymerizable | 1.9NDA | 1.9NDA | 1.9NDA |
| | | composition | | | |
| | | Amount (part by mass) | 0.54 | 0.54 | 0.54 |
| | | Photopolymerization | Irg819 | Irg819 | Irg819 |
| | | initiator | | | |
| | | Amount (part by mass) | 0.003 | 0.003 | 0.003 |
| Substrate | | Barrier film | Barrier film 14 | Barrier film 14 | Barrier film 14 |
| End face | First | Material | Ti | Al | Ti |
| sealing | layer | Film thickness [μm] | 0.01 | 0.03 | 0.01 |
| layer | | Film forming method | Sputtering | Sputtering | Sputtering |
| | Second | Material | Cu | Ni | Cu |
| | layer | Film thickness [μm] | 0.2 | 0.075 | 0.2 |
| | | Film forming method | Sputtering | Sputtering | Sputtering |
| | Third | Material | Cu | Cu | Cu |
| | layer | Film thickness [μm] | 10 | 6 | 5 |
| | | Film forming method | Electroplating | Electroplating | Electroplating |

| | | | | |
|---|---|---|---|---|
| Evaluation | Modulus of elasticity at | 18 | 18 | 18 |
| | 50° C. [MPa] | | | |
| | Sealing performance | A | A | A |
| | Adhesiveness | A | A | A |

| Reagent list | Detail | Maker |
|---|---|---|
| Dicyclopentanyl acrylate | Aliphatic monofunctional (meth)acrylate compound | Manufactured by TOKYO CHEMICAL INDUSTRY CO., LTD. |
| 1,9 NDA | Difunctional (meth)acrylate compound | Manufactured by SHIN-NAKAMURA CHEMICAL CO., LTD. |

TABLE 1-6

| | | | Comparative | Comparative | Comparative | Comparative |
|---|---|---|---|---|---|---|
| | | | Example 1 | Example 2 | Example 3 | Example 4 |
| Optically functional | | Quantum dot 1 | Toluene | Toluene | Toluene | Toluene |
| layer | | | dispersion liquid | dispersion liquid | dispersion liquid | dispersion liquid |
| | | | of quantum dot 1 | of quantum dot 1 | of quantum dot 1 | of quantum dot 1 |
| | | Amount (part by mass) | 10 | 10 | 10 | 10 |
| | | Quantum dot 2 | Toluene | Toluene | Toluene | Toluene |
| | | | dispersion liquid | dispersion liquid | dispersion liquid | dispersion liquid |
| | | | of quantum dot 2 | of quantum dot 2 | of quantum dot 2 | of quantum dot 2 |
| | | Amount (part by mass) | 1 | 1 | 1 | 1 |
| | | First polymerizable | Lauryl acrylate | Benzyl acrylate | — | — |
| | | composition | | | | |
| | | Amount (part by mass) | 2.98 | 2.98 | — | — |
| | | Second polymerizable | — | — | A-TMMT | DPHA |
| | | composition | | | | |
| | | Amount (part by mass) | — | — | 2.98 | 2.98 |
| | | Photopolymerization | Irg819 | Irg819 | Irg819 | Irg819 |
| | | initiator | | | | |
| | | Amount (part by mass) | 0.003 | 0.003 | 0.003 | 0.003 |
| Substrate | | Barrier film | Barrier film 14 | Barrier film 14 | Barrier film 14 | Barrier film 14 |
| End face | First | Material | Ti | Ti | Ti | Ti |
| sealing layer | Layer | Film thickness [μm] | 0.01 | 0.01 | 0.01 | 0.01 |
| | | Film forming method | Sputtering | Sputtering | Sputtering | Sputtering |
| | Second | Material | Cu | Cu | Cu | Cu |
| | layer | Film thickness [μm] | 0.2 | 0.2 | 0.2 | 0.2 |
| | | Film forming method | Sputtering | Sputtering | Sputtering | Sputtering |
| | Third | Material | Cu | Cu | Cu | Cu |
| | layer | Film thickness [μm] | 5 | 5 | 5 | 5 |
| | | Film forming method | Electroplating | Electroplating | Electroplating | Electroplating |

| Evaluation | Modulus of elasticity at | Unmeasurable (<1 MPa) | Unmeasurable (<1 MPa) | 4200 | 4700 |
|---|---|---|---|---|---|
| | 50° C. [MPa] | | | | |
| | Sealing performance | D | D | D | D |
| | Adhesiveness | B | A | B | B |

| Reagent list | Detail | Maker |
|---|---|---|
| Lauryl acrylate | Aliphatic monofunctional (meth)acrylate compound | Manufactured by TOKYO CHEMICAL INDUSTRY CO., LTD. |
| Benzyl acrylate | Aromatic monofunctional (meth)acrylate compound | Manufactured by TOKYO CHEMICAL INDUSTRY CO., LTD. |
| A-TMMT | Tetrafunctional (meth)acrylate compound | Manufactured by SHIN-NAKAMURA CHEMICAL CO., LTD. |
| DPHA | Hexafunctional (meth)acrylate compound | Manufactured by SHIN-NAKAMURA CHEMICAL CO., LTD. |

As shown in Table 1 (Table 1-1 to Table 1-6), it is understood that in the examples of the laminated film of the second aspect of the present invention, the area of the non-light-emitting region of the edge is further reduced than in the comparative examples, and oxygen and water are blocked by the end face sealing layer including two or more metal layers, and hence the deterioration of the quantum dot layer (optically functional layer) can be prevented.

As is evident from the comparison between the examples and the comparative examples, in a case where a monofunctional polymerizable compound and a polyfunctional polymerizable compound are used in combination, and a modulus of elasticity is within a predetermined range, the matrix of the optically functional layer ensures the film stress at the time of forming a metal thin film, no defect occurs in the metal thin film of the end face, smoothness can be secured, and an end face sealing layer having high barrier properties is formed on the end face.

### Example 24

Then, for the laminated film of the first aspect of the present invention, the laminated film 10b shown in FIG. 3 was prepared as Example 24.

The laminated film of Example 24 was prepared in the same manner as in Example 1, except that the composition of the coating solution for forming an optically functional layer was changed to the following composition, and in the sheet processing step, after 1,000 sheets of the laminates cut in the form of a sheet were stacked, the end face of the laminate was cut using RETRATOME REM-710 manufactured by YAMATO KOHKI INDUSTRIAL CO., LTD under the condition of a blade edge angle of 0° and a cutting depth of 10 μm so as to adjust the surface roughness of the end face.

The surface roughness Ra of the end face of the prepared functional layer laminate 11 was measured using an interference microscope (vertscan 2.0 manufactured by MITSUBISHI CHEMICAL SYSTEMS, Inc.). As a result, the surface roughness Ra was 0.6 μm.

(Composition of Coating Solution for Forming Optically Functional Layer)

| | | |
|---|---|---|
| Toluene dispersion liquid of quantum dot 1 | 10 | parts by mass |
| (emission maximum: 520 nm) | | |
| Toluene dispersion liquid of quantum dot 2 | 1 | part by mass |
| (emission maximum: 630 nm) | | |
| Lauryl methacrylate | 2.4 | parts by mass |
| Trimethylolpropane triacrylate | 0.54 | parts by mass |
| Photopolymerization initiator (IRGACURE 819 | 0.009 | parts by mass |
| (manufactured by BASF SE)) | | |

### Examples 25 to 29

The laminated film 10b was prepared in the same manner as in Example 24, except that the material and the film thickness of each of the first layer 18, the second layer 22, and the outermost layer 20 as well as the surface roughness Ra of the end face of the functional layer laminate 11 were changed as shown in the following Table 2.

In Example 27, end face cutting was performed under the condition of a blade edge angle of 0° and a cutting depth of 20 μm. In Example 29, end face cutting was performed under the condition of a blade edge angle of 25° and a cutting depth of 20 μm.

### Example 30

The laminated film 10a was prepared in the same manner as in Example 24, except that the laminated film was constituted with two layers including the first layer 18 and the outermost layer 20 without forming the second layer 22, and the material and the film thickness of the first layer 18 were changed as shown in the following Table 2.

### Comparative Example 5

A laminated film was prepared in the same manner as in Example 24, except that the end face sealing layer was not formed.

### Comparative Example 6

A laminated film was prepared in the same manner as in Example 24, except that an end face sealing layer was constituted with a single layer, and the material and the film thickness of this layer were changed as shown in the following Table 2.

### Comparative Example 7

As an end face sealing layer, LOCTITE E-30CL manufactured by Henkel Japan Ltd was formed on the end face of the functional layer laminate by a dipping method.

[Evaluation]

<Evaluation of End Face Sealing Performance>

For the prepared laminated films of Examples 24 to 30 and Comparative Examples 5 to 7, the end face sealing performance was evaluated in the same manner as described above.

<Evaluation of Adhesiveness>

For the prepared laminated films of Examples 24 to 30 and Comparative Examples 5 to 7, the adhesiveness was evaluated in the same manner as described above.

<Evaluation of Number of Pinholes>

The number of pinholes in the end face sealing layer of the prepared laminated films was measured as below.

The end face sealing layer on four sides was observed, an uncoated portion having a size of equal to or greater than 1 μm was regarded as a pinhole. The number x of the pinholes was measured, and the number of pinholes per 1 mm² was calculated.

By using the number of pinholes as a parameter, the laminated films were evaluated based on the following standards. In a case where the evaluation result is C or better, it is possible to make a judgment that the end face sealing layer has a small number of pinholes and sufficient gas barrier properties.

A: x≤5 pinholes/mm²

B: 5 pinholes/mm²<x<10 pinholes/mm²

C: 10 pinholes/mm²≤x<20 pinholes/mm²

D: 20 pinholes/mm²≤x

<Evaluation of Wrapping Width>

The wrapping width of the end face sealing layer on the main surface of the prepared laminated film was measured as below.

The laminated film was subjected to cross-section cutting by using RETRATOME REM-710 manufactured by YAMATO KOHKI INDUSTRIAL CO., LTD under the condition of a blade edge angle of 0° and a cutting depth of 10 μm. The cross-section was observed with an optical microscope, and the wrapping width d was determined.

By using the wrapping width d as a parameter, the laminated film was evaluated based on the following standards. In a case where the evaluation result is C or better, it is possible to make a judgment that the wrapping width is small, and the occurrence of a non-light-emitting portion at the edge of the film can be inhibited.

A: d≤0.1 mm

B: 0.1 mm<d<0.5 mm

C: 0.5 mm≤d<1 mm

D: 1 mm≤d

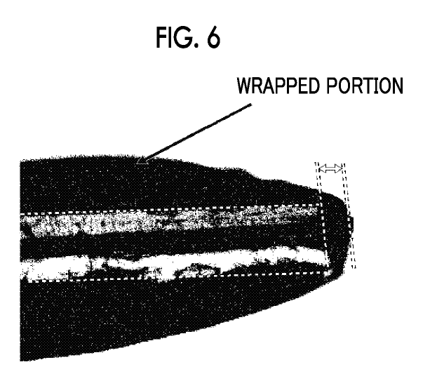

An optical micrograph of a cross-section of the end face of the laminated film of Comparative Example 7 is shown in FIG. 6.

The results are shown in the following Table 2.

TABLE 2

| | End face sealing layer | | | | | | | | | |
|---|---|---|---|---|---|---|---|---|---|---|
| | First layer | | | Second layer | | | Outermost layer | | | |
| | | Film | Film | | Film | Film | | Film | | Total film |
| | | thickness | forming | | thickness | forming | | thickness | Film forming | thickness |
| | Material | μm | method | Material | μm | method | Material | μm | method | μm |
| Example 24 | Ti | 0.01 | Sputtering | Cu | 0.075 | Sputtering | Cu | 5 | Electroplating | 5.1 |
| Example 25 | Ti | 0.03 | Sputtering | Cu | 0.2 | Sputtering | Cu | 5 | Electroplating | 5.2 |
| Example 26 | Ti | 0.01 | Sputtering | Cu | 0.075 | Sputtering | Cu | 10 | Electroplating | 10.1 |
| Example 27 | Ti | 0.01 | Sputtering | Cu | 0.075 | Sputtering | Cu | 5 | Electroplating | 5.1 |
| Example 28 | Al | 0.03 | Sputtering | Ni | 0.075 | Sputtering | Ni | 6 | Electroplating | 6.1 |
| Example 29 | Ti | 0.03 | Sputtering | Cu | 0.2 | Sputtering | Cu | 5 | Electroplating | 5.2 |

| | | | | | | | | |
|---|---|---|---|---|---|---|---|---|
| Example 30 | Cu | 0.075 | Sputtering | — | Cu | 5 | Electroplating | 5.1 |

| Comparative | — | | | — | — | — |
|---|---|---|---|---|---|---|
| Example 5 | | | | | | |
| Comparative | Cu | 0.3 | Sputtering | — | — | 0.3 |
| Example 6 | | | | | | |
| Comparative | E-30CL | 60 | Dipping | — | — | 60.0 |
| Example 7 | | | | | | |

| | Functional layer | | | | |
|---|---|---|---|---|---|
| | laminate | Evaluation | | | |
| | End face Surface | Sealing | | Number of | Wrapping |
| | roughness μm | performance | Adhesiveness | pinholes | width |
| Example 24 | 0.6 | A | A | A | A |
| Example 25 | 0.6 | A | B | A | A |
| Example 26 | 0.6 | A | B | A | A |
| Example 27 | 1.7 | B | A | B | B |
| Example 28 | 0.6 | A | A | A | B |
| Example 29 | 5.6 | C | A | C | B |
| Example 30 | 0.6 | B | B | B | B |
| Comparative | 0.6 | D | — | — | — |
| Example 5 | | | | | |
| Comparative | 0.6 | D | A | D | A |
| Example 6 | | | | | |
| Comparative | 0.2 | D | A | — | D |
| Example 7 | | | | | |

As shown in Table 2, it is understood that in the examples of the laminated film of the first aspect of the present invention, the area of the non-light-emitting region at the edge is further reduced than in the comparative examples, oxygen and water are blocked by the end face sealing layer including two or more metal layers, and hence the deterioration of the quantum dots (optically functional layer) can be prevented.

Furthermore, from the comparison between Example 24, Example 26, and Comparative Example 6, it is understood that the thicker the end face sealing layer, the lower the oxygen permeability, and the higher the sealing performance.

From the comparison between Example 24, Example 27, and Example 29, it is understood that the smaller the surface roughness Ra of the functional layer laminate, the higher the sealing performance, for the following reason. Presumably, the greater the surface roughness Ra of the functional layer laminate is, the more difficult it is for the laminate to be uniformly coated with the end face sealing layer, and hence pinholes occur. This result shows that it is preferable that the surface roughness Ra of the functional layer laminate is equal to or smaller than 2.0 μm.

From the comparison between Example 24, Example 28, and Example 30, it is understood that in a case where any one of aluminum, titanium, chromium, and nickel is used as the material of the first layer contacting the end face of the functional layer laminate, higher adhesiveness is obtained.

The above results clearly show the effects of the present invention.

### EXPLANATION OF REFERENCES

10a, 10b: laminated film
11: functional layer laminate
12: optically functional layer
14: gas barrier layer (gas barrier film)
16a, 16b: end face sealing layer
18, 18A: first layer
20, 20A: outermost layer
22: second layer
30: gas barrier support
32: barrier layer
34: organic layer
36: inorganic layer
38: organic layer
50: laminated material
52: laminated material in which first layer is formed
54: laminated material in which outermost layer is formed.

What is claimed is:

1. A laminated film comprising:
a functional layer laminate having an optically functional layer and a gas barrier layer laminated on at least one main surface of the optically functional layer; and
an end face sealing layer formed by covering at least a portion of an end face of the functional layer laminate,
wherein the end face sealing layer includes at least two layers, and
each of the layers included in the end face sealing layer is formed of a metal.

2. The laminated film according to claim 1,
wherein at least one layer included in the end face sealing layer other than a first layer included in the end face sealing layer that contacts the functional layer laminate is a metal plating layer.

3. The laminated film according to claim 1,
wherein an outermost layer included in the end face sealing layer that is farthest from the functional layer laminate is a metal plating layer.

4. The laminated film according to claim 2,
wherein a thickness of the metal plating layer is greater than a thickness of the first layer that contacts the functional layer laminate.

5. The laminated film according to claim 4,
wherein the thickness of the first layer is 0.001 μm to 0.5 μm, and
the thickness of the metal plating layer is 0.01 μm to 100 μm.

6. The laminated film according to claim 1,
wherein a material of the first layer that contacts the functional layer laminate is either at least one kind of metal selected from the group consisting of aluminum, titanium, chromium, copper, and nickel or an alloy containing at least one kind of these metals, and
a material of each of the layers included in the end face sealing layer other than the first layer is either at least one kind of metal selected from the group consisting of aluminum, titanium, chromium, nickel, tin, copper, silver, and gold or an alloy containing at least one kind of these metals.

7. The laminated film according to claim 1,
wherein a thickness of the end face sealing layer is 0.1 μm to 100 μm.

8. A laminated film comprising:
a functional layer laminate having an optically functional layer and a gas barrier layer laminated on at least one main surface of the optically functional layer, and
an end face sealing layer formed by covering at least a portion of an end face of the functional layer laminate,
wherein the end face sealing layer includes at least two layers,
each of the layers included in the end face sealing layer is formed of a metal, and
the optically functional layer is a cured layer obtained by curing a polymerizable composition containing phosphors and at least two or more kinds of polymerizable compounds.

9. The laminated film according to claim 8,
wherein the polymerizable compounds include at least one kind of first polymerizable compound formed of a monofunctional polymerizable compound and at least one kind of second polymerizable compound formed of a polyfunctional polymerizable compound.

10. The laminated film according to claim 9,
wherein the first polymerizable compound is aliphatic or aromatic alkyl (meth)acrylate containing an alkyl group having 4 to 30 carbon atoms, and
the second polymerizable compound is selected from 1,6-hexanediol diacrylate, 1,10-decanediol diacrylate, 1,9-nonanediol di(meth)acrylate, tricyclodecanedimethanol diacrylate, dicyclopentanyl di(meth)acrylate, and ethoxylated bisphenol A diacrylate.

11. The laminated film according to claim 8,
wherein a modulus of elasticity of the optically functional layer at 50° C. is 1 MPa to 4,000 MPa.

12. The laminated film according to claim 8,
wherein the gas barrier layer is laminated on both the main surfaces of the optically functional layer.

13. The laminated film according to claim 8,
wherein the phosphors in the optically functional layer are quantum dots, quantum rods, or tetrapod-type quantum dots.

14. The laminated film according to claim 8,
wherein at least one layer included in the end face sealing layer other than the first layer that contacts the functional layer laminate is a metal plating layer.

15. The laminated film according to claim 8,
wherein the outermost layer included in the end face sealing layer that is farthest from the functional layer laminate is a metal plating layer.

16. The laminated film according to claim 14,
wherein a thickness of the metal plating layer is greater than a thickness of the first layer that contacts the functional layer laminate.

17. The laminated film according to claim 16,
wherein the thickness of the first layer is 0.001 μm to 0.5 μm, and
the thickness of the metal plating layer is 0.01 μm to 100 μm.

18. The laminated film according to claim 8,
wherein a material of the first layer that contacts the functional layer laminate is either at least one kind of metal selected from the group consisting of aluminum, titanium, chromium, copper, and nickel or an alloy containing at least one kind of these metals, and
a material of each of the layers included in the end face sealing layer other than the first layer is either at least one kind of metal selected from the group consisting of aluminum, titanium, chromium, nickel, tin, copper, silver, and gold or an alloy containing at least one kind of these metals.

19. The laminated film according to claim 8,
wherein a thickness of the end face sealing layer is 0.1 μm to 100 μm.
